(19) United States
(12) Patent Application Publication
(10) Pub. No.: US 2025/0167131 A1
(43) Pub. Date: May 22, 2025

(54) OPTICAL PACKAGE STRUCTURE

(71) Applicant: Advanced Semiconductor Engineering, Inc., Kaohsiung (TW)

(72) Inventors: Hsun-Wei CHAN, Kaohsiung (TW); Shih-Chieh TANG, Kaohsiung (TW); Lu-Ming LAI, Kaohsiung (TW); Tzu Hui CHEN, Kaohsiung (TW)

(73) Assignee: Advanced Semiconductor Engineering, Inc., Kaohsiung (TW)

(21) Appl. No.: 18/511,996

(22) Filed: Nov. 16, 2023

(51) Int. Cl. H01L 23/552; H01L 21/48; H01L 23/00; H01L 25/16

(52) U.S. Cl. CPC H01L 23/552; H01L 21/4857; H01L 21/486; H01L 25/165; H01L 25/167; H01L 24/48; H01L 2224/48091; H01L 2224/48227

(57) ABSTRACT

An optical package structure is provided. The optical package structure includes a first substrate, a second substrate, a first optical component, a second optical component, and an electrical shielding element. The second substrate is over the first substrate. The first substrate and the second substrate collectively define a first cavity. The first optical component is disposed in the first cavity. The second optical component is disposed over the first substrate. The electrical shielding element is disposed adjacent to a sidewall of the first cavity and between the first optical component and the second optical component.

### BACKGROUND

### 1. Technical Field

The present disclosure relates generally to an optical package structure.

### 2. Description of the Related Art

Liquid crystal polymer (LCP) lid may be used for optical shielding between an emitter and a receiver of an optical package structure, and the emitter is usually electrically connected to a substrate of the optical package structure through a bond wire. However, the LCP lid usually has a relatively large thickness, and the loop height of the bond wire may increase the overall thickness of the optical package structure.

### SUMMARY

In one or more arrangements, an optical package structure includes a first substrate, a second substrate, a first optical component, a second optical component, and an electrical shielding element. The second substrate is over the first substrate. The first substrate and the second substrate collectively define a first cavity. The first optical component is disposed in the first cavity. The second optical component is disposed over the first substrate. The electrical shielding element is disposed adjacent to a sidewall of the first cavity and between the first optical component and the second optical component.

In one or more arrangements, an optical package structure includes a first substrate, a second substrate, an adhesive layer, and a shielding structure. The first substrate includes a first circuit structure. The second substrate includes a second circuit structure. The adhesive layer is between the first substrate and the second substrate. The shielding structure is at least partially encapsulated by the adhesive layer and configured to reduce an electromagnetic interference between the first circuit structure and the second circuit structure.

In one or more arrangements, an optical package structure includes a substrate structure, an optical receiver, and a limitation structure. The optical receiver is over the substrate structure. The limitation structure is over the substrate structure and configured to reduce a first light reflected from the limitation structure to the optical receiver.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of an optical package structure in accordance with some arrangements of the present disclosure.

FIG. 1B is a top view of an optical package structure in accordance with some arrangements of the present disclosure.

FIG. 1C is a cross-section of an optical package structure in accordance with some arrangements of the present disclosure.

FIG. 1D is a cross-section of an optical package structure in accordance with some arrangements of the present disclosure.

FIG. 2A is a cross-section of an optical package structure in accordance with some arrangements of the present disclosure.

FIG. 2B is a cross-section of an optical package structure in accordance with some arrangements of the present disclosure.

FIG. 2C is a cross-section of an optical package structure in accordance with some arrangements of the present disclosure.

FIG. 3A is a cross-section of an optical package structure in accordance with some arrangements of the present disclosure.

FIG. 3B is a cross-section of an optical package structure in accordance with some arrangements of the present disclosure.

FIG. 3C is a cross-section of an optical package structure in accordance with some arrangements of the present disclosure.

FIG. 4A is a cross-section of an optical package structure in accordance with some arrangements of the present disclosure.

FIG. 4B is a cross-section of an optical package structure in accordance with some arrangements of the present disclosure.

FIG. 4C is a cross-section of an optical package structure in accordance with some arrangements of the present disclosure.

FIG. 4D is a cross-section of an optical package structure in accordance with some arrangements of the present disclosure.

FIG. 4E is a cross-section of an optical package structure in accordance with some arrangements of the present disclosure.

FIG. 4F is a cross-section of an optical package structure in accordance with some arrangements of the present disclosure.

FIG. 5A is a cross-section of an optical package structure in accordance with some arrangements of the present disclosure.

FIG. 5B is a top view of an optical package structure in accordance with some arrangements of the present disclosure.

FIG. 5C is a cross-section of an optical package structure in accordance with some arrangements of the present disclosure.

FIG. 5D is a top view of an optical package structure in accordance with some arrangements of the present disclosure.

FIG. 6A, FIG. 6B, FIG. 6C, FIG. 6D, FIG. 6E, FIG. 6F, FIG. 6G, FIG. 6H, FIG. 6I, and FIG. 6J illustrate various stages of an exemplary method for manufacturing an optical package structure in accordance with some arrangements of the present disclosure.

FIG. 7A, FIG. 7B, FIG. 7C, FIG. 7D, FIG. 7E, FIG. 7F, FIG. 7G, FIG. 7H, FIG. 7I, FIG. 7J, and FIG. 7K illustrate various stages of an exemplary method for manufacturing an optical package structure in accordance with some arrangements of the present disclosure.

FIG. 8A, FIG. 8B, FIG. 8C, FIG. 8D, and FIG. 8E illustrate various stages of an exemplary method for manufacturing an optical package structure in accordance with some arrangements of the present disclosure.

Common reference numerals are used throughout the drawings and the detailed description to indicate the same or similar elements.

### DETAILED DESCRIPTION

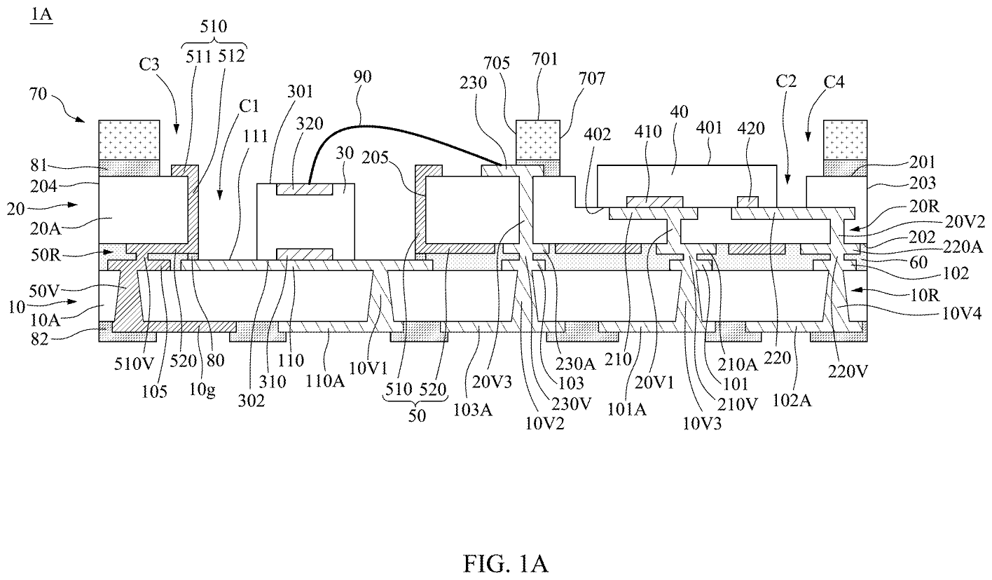

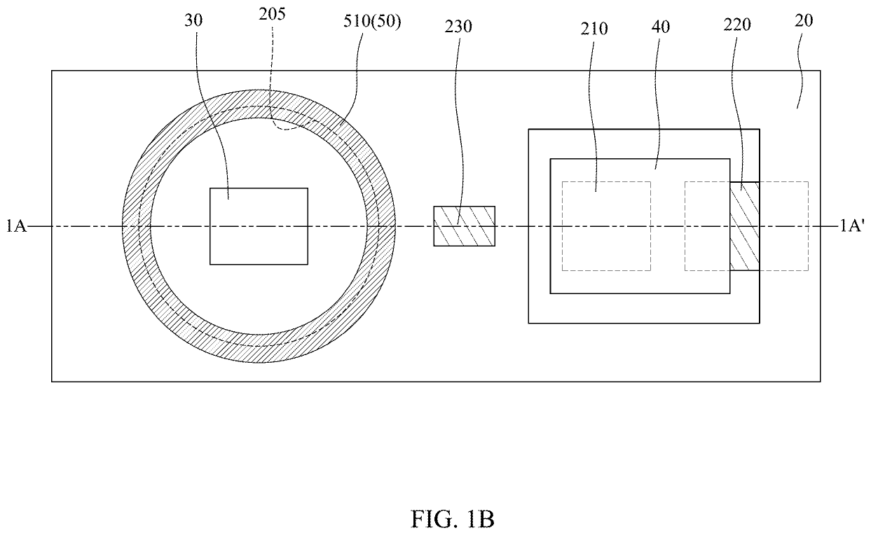

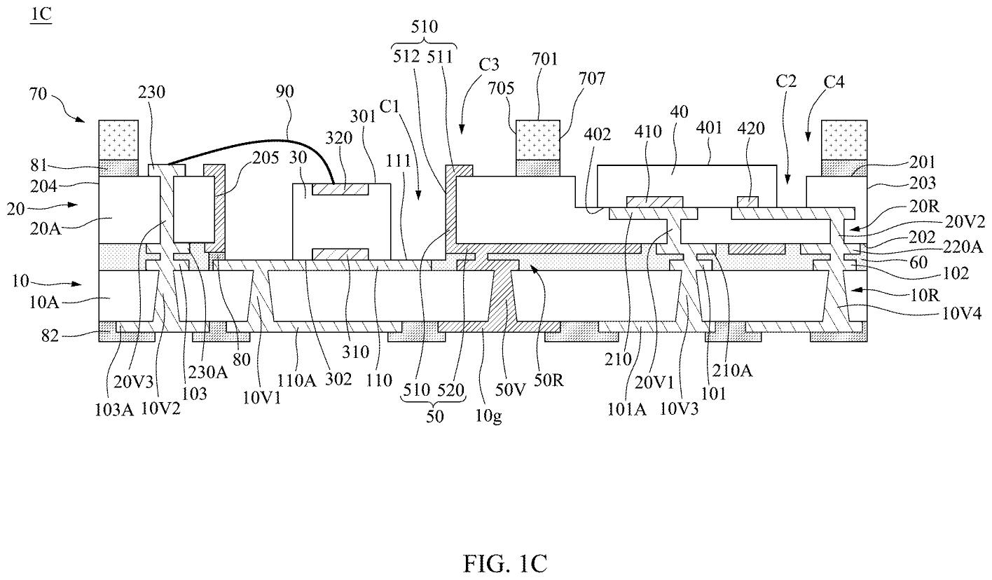

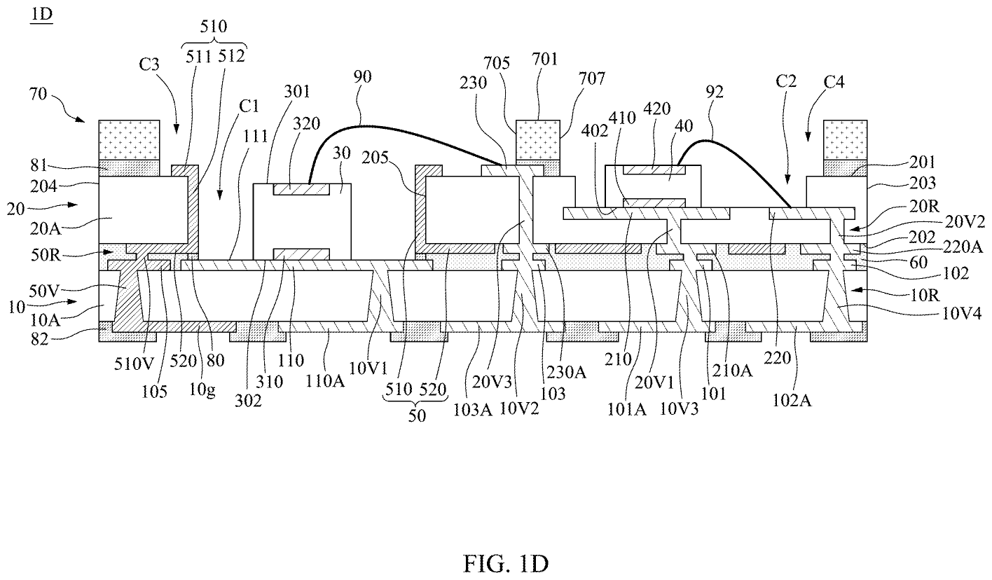

FIG. 1A is a cross-section of an optical package structure 1A in accordance with some arrangements of the present disclosure. FIG. 1B is a top view of an optical package structure 1A in accordance with some arrangements of the present disclosure. In some arrangements, FIG. 1A is a cross-section along a line 1A-1A′ in FIG. 1B. The optical package structure 1A may include substrates 10 and 20, optical components, a shielding structure, an adhesive layer 60, a barrier 70, protective layers 80, 81, and 82, and a conductor (e.g., a conductive wire 90).

The substrates 10 and 20 may independently include, for example, a printed circuit board, such as a paper-based copper foil laminate, a composite copper foil laminate, or a polymer-impregnated glass-fiber-based copper foil laminate. The substrates 10 and 20 may independently include an interconnection structure, which may include such as a plurality of conductive traces and/or a plurality of conductive vias. The interconnection structure may include a redistribution layer (RDL) and/or a grounding element. In some arrangements, the substrates 10 and 20 may independently include an organic substrate or a leadframe. In some arrangements, the substrates 10 and 20 may independently include a ceramic material or a metal plate. In some arrangements, the substrates 10 and 20 may independently include a two-layer substrate which includes a core layer and a conductive material and/or structure disposed on an upper surface (or a top surface) and a lower surface (or a bottom surface) of the substrate. The substrates 10 and 20 may independently include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. The substrates 10 and 20 may independently include one or more conductive elements, surfaces, contacts, or pads.

In some arrangements, the substrate 10 includes a base layer 10A and a circuit structure 10R. The base layer 10A may be or include a semiconductor layer or a dielectric layer. In some arrangements, the circuit structure 10R includes a plurality of conductive layers (e.g., conductive layers 110, 101, 102, 103, 101A, 102A, 103A, and 10g) and a plurality of conductive vias (e.g., conductive vias 10V1, 10V2, 10V3, and 10V4) electrically connected to corresponding conductive layers. In some arrangements, the conductive vias 10V1, 10V2, 10V3, and 10V4 penetrate the base layer 10A. In some arrangements, the conductive vias 10V1, 10V2, 10V3, and 10V4 taper toward the substrate 20. In some arrangements, the conductive layer 10g may serve as or connect to a ground element.

In some arrangements, the substrate 20 is disposed over the substrate 10. In some arrangements, the substrate 20 is electrically connected to the substrate 10. In some arrangements, the substrates 10 and 20 collectively define a cavity C1 (also referred to as “a recess” or “a space”). The cavity C1 may accommodate one or more optical components. In some arrangements, the conductive layer 110 (or a top surface 111 of the substrate 10) is exposed to the cavity C1. In some arrangements, the substrate 20 includes the cavity C1. In some arrangements, the substrate 20 further includes or defines a cavity C2 (also referred to as “a recess” or “a space”). The cavity C2 may accommodate one or more optical components. In some arrangements, the substrate 20 includes a base layer 20A and a circuit structure 20R. The base layer 20A may be or include a semiconductor layer or a dielectric layer. In some arrangements, the circuit structure 20R includes a plurality of conductive layers (e.g., conductive layers 210, 220, 230, 210A, 220A, and 230A) and a plurality of conductive vias (e.g., conductive vias 20V1, 20V2, and 20V3) electrically connected to corresponding conductive layers. In some arrangements, the conductive vias 20V1, 20V2, and 20V3 penetrate the base layer 20A. In some arrangements, the conductive layers 210 and 220 are exposed to the cavity C2. In some arrangements, the circuit structure 20R is disposed over the circuit structure 10R. The substrate 20 may have a surface 201 (also referred to as “a top surface”), a surface 202 opposite to the surface 201, surfaces 203 and 204 (also referred to as “lateral surface”) extending between the surface 201 and the surface 202.

In some arrangements, the conductive layer, pads, or contacts may independently include a conductive material such as a metal or metal alloy. Examples include gold (Au), silver (Ag), aluminum (Al), copper (Cu), or an alloy thereof. The dielectric layers may independently include an organic material, a solder mask, PI, an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like. In some arrangements, the substrate 10 is referred to as a substrate structure of the optical package structure 1A. In some arrangements, the substrates 10 and 20 construct a substrate structure of the optical package structure 1A.

The optical emitter 30 (also referred to as “optical emitting device” or “light emitting device”) may be embedded in the substrate structure. In some arrangements, the optical emitter 30 is disposed in the cavity C1. In some arrangements, the optical emitter 30 is electrically connected to the substrate 10. In some arrangements, the optical emitter 30 is disposed on the circuit structure 10R. In some arrangements, the optical emitter 30 is electrically connected to the circuit structure 10R. In some arrangements, the optical emitter 30 is electrically connected to the substrate 20. In some arrangements, the optical emitter 30 is wire-bonded to the substrate 20. In some arrangements, the conductor (e.g., the conductive wire 90) is directly connected to the optical emitter 30 and the substrate 20. In some arrangements, the optical emitter 30 has a surface 301 (also referred to as “a top surface”) and a surface 302 opposite to the surface 301. In some arrangements, the surface 301 is electrically connected to the conductive layer 230 through the conductive wire 90 (or the conductor), and the surface 302 is electrically connected to the conductive layer 110. In some arrangements, the optical emitter 30 includes two electrodes 310 and 320 on opposite surfaces (e.g., the surfaces 301 and 302) electrically connected to the conductive layer 110 and the conductive layer 230, respectively. In some arrangements, the electrode 310 is electrically connected to the conductive layer 110A through the conductive layer 110 and the conductive via 10V1. In some arrangements, the electrode 320 is electrically connected to the substrate 10 through the conductive wire 90, the conductive layer 230, the conductive via 20V3, and the conductive layer 230A. In some arrangements, the electrode 320 is electrically connected to the conductive layer 103A through the conductive wire 90, the substrate 20, a conductive via 230V, the conductive layer 103, and the conductive via 10V2.

The optical receiver 40 (also referred to as “optical receiving device” or “light receiving device”) may be disposed over the substrate structure. In some arrangements, the optical receiver 40 is disposed over the substrate 10. In some arrangements, the optical receiver 40 is disposed in the cavity C2. In some arrangements, the optical receiver 40 is electrically connected to the substrate 20. In some arrangements, the optical receiver 40 is disposed on the circuit structure 20R. In some arrangements, the optical receiver 40 is electrically connected to the circuit structure 20R. In some arrangements, the optical receiver 40 is flip-chip bonded to the substrate 20. In some arrangements, the optical receiver 40 has a surface 401 (also referred to as “a top surface”) and a surface 402 opposite to the surface 401. In some arrangements, the surface 302 is electrically connected to the conductive layers 210 and 220. In some arrangements, the optical receiver 40 includes two electrodes 410 and 420 on the surface 402 electrically connected to the conductive layers 210 and 220, respectively. In some arrangements, the electrode 410 is electrically connected to the conductive layer 101A through the conductive layer 210, the conductive via 20V1, the conductive layer 210A, a conductive via 210V, the conductive layer 101, and the conductive via 10V3. In some arrangements, the electrode 420 is electrically connected to the conductive layer 102A through the conductive layer 220, the conductive via 20V2, the conductive layer 220A, a conductive via 220V, the conductive layer 102, and the conductive via 10V4. In some arrangements, an elevation of the optical receiver 40 is higher than an elevation of the optical emitter 30 with respect to the substrate 10. In some arrangements, the surface 401 (or the top surface) of the optical receiver 40 is higher than an elevation of a top portion of the cavity C1 with respect to the substrate 10.

In some arrangements, the shielding structure may be configured to reduce an electromagnetic interference between the circuit structure 10R and the circuit structure 20R. In some arrangements, the shielding structure may include a portion between the optical emitter 30 and the optical receiver 40 and configured to reduce a light interference therebetween. In some arrangements, the shielding structure may further include a connection portion extending into the substrate 10 and electrically connected to a ground element of the substrate 10. In some arrangements, the shielding structure may include an electrical shielding element 50, a connection portion 50R (also referred to as “a connection element”), and a via portion 50V (also referred to as “a conductive via”). In some arrangements, the shielding structure is at least partially encapsulated by the adhesive layer 60. In some arrangements, the shielding structure may include a conductive material, for example, a metal material. The examples may include aluminum (Al), copper (Cu), chromium (Cr), tin (Sn), gold (Au), silver (Ag), nickel (Ni) or stainless steel, or a mixture, an alloy, or other combination thereof.

In some arrangements, the electrical shielding element 50 includes a portion 510 (also referred to as “a vertical portion”) and a portion 520 (also referred to as “a horizontal portion”). In some arrangements, the electrical shielding element 50 (or the portion 510) is disposed between the optical emitter 30 and the optical receiver 40. In some arrangements, the portion 510 is configured to reduce a light interference between the optical emitter 30 and the optical receiver 40. In some arrangements, the portion 510 is referred to as a block structure disposed adjacent to the cavity C1 and configured to reflect a light from the optical emitter 30. In some arrangements, the electrical shielding element 50 (or the portion 510) is disposed adjacent to a sidewall 205 of the cavity C1. In some arrangements, the electrical shielding element 50 (or the portion 510) covers the sidewall 205 of the cavity C1. In some arrangements, the electrical shielding element 50 (or the portion 510) extends along the sidewall 205 of the cavity C1. In some arrangements, the electrical shielding element 50 (or the portion 510) extends along the sidewall 205 to an end portion (e.g., the surface 202) of the substrate 20 facing the substrate 10. In some arrangements, the portion 510 further includes a vertical part 512 and an extension 511. In some arrangements, the extension 511 partially covers the surface 201 of the substrate 20. In some arrangements, the vertical part 512 covers the sidewall 205 of the cavity C1. In some arrangements, referring to FIG. 1B, the electrical shielding element 50 (or the portion 510) surrounds the optical emitter 30. In some arrangements, the conductive layer 110 is exposed to the cavity C1 and spaced apart from the electrical shielding element 50.

In some arrangements, the electrical shielding element 50 (or the portion 520) is between the circuit structure 10R and the circuit structure 20R. In some arrangements, the circuit structure 20R at least partially vertically overlaps the portion 520 of the shielding structure. In some arrangements, the portion 520 is disposed on the surface 202 of the substrate 20. In some arrangements, the portion 520 includes a plurality of horizontal parts between the conductive layers 210A, 220A, and 230A.

In some arrangements, the connection portion 50R (or the connection element) electrically connects the electrical shielding element 50 to a ground element (e.g., the conductive layer 10g). In some arrangements, the portion 510 is electrically connected to the ground element (e.g., the conductive layer 10g) through the connection portion 50R. In some arrangements, the connection portion 50R includes a conductive via 510V and a conductive layer 105. The portion 510 is electrically connected to the ground element (e.g., the conductive layer 10g) through the conductive via 510V and the conductive layer 105.

In some arrangements, the via portion 50V (or the conductive via) is disposed or formed in the substrate 10 and electrically connects the connection portion 50R to the ground element (e.g., the conductive layer 10g). In some arrangements, the via portion 50V extends into the substrate 10 and electrically connects to the ground element (e.g., the conductive layer 10g). In some arrangements, the via portion 50V penetrates the base layer 10A of the substrate 10. In some arrangements, the via portion 50V tapers toward the substrate 20.

The adhesive layer 60 may between the substrate 10 and the substrate 20. In some arrangements, the adhesive layer 60 is configured to adhere the substrate 10 and the substrate 20. In some arrangements, the adhesive layer 60 encapsulates the portion 520 and the connection portion 50R. In some arrangements, the adhesive layer 60 encapsulates the portion 520, the conductive via 510V, and the conductive layer 105. In some arrangements, the adhesive layer 60 directly contacts the electrical shielding element 50 (or the portion 520). In some arrangements, the adhesive layer 60 directly contacts the portion 520, the conductive via 510V, and the conductive layer 105. In some arrangements, the adhesive layer 60 at least partially encapsulates the conductive layers 110, 102, 103, and 104 of the circuit structure 10R. In some arrangements, the adhesive layer 60 directly contacts the conductive layers 110, 102, 103, and 104 of the circuit structure 10R. In some arrangements, the adhesive layer 60 at least partially encapsulates the conductive layers 210A, 220A, and 230A of the circuit structure 20R. In some arrangements, the adhesive layer 60 directly contacts the conductive layers 210A, 220A, and 230A of the circuit structure 20R. In some arrangements, the adhesive layer 60 is spaced apart from the cavity C1. In some arrangements, the conductive layer 110 is exposed to the cavity C1 and spaced apart from the electrical shielding element 50 by the adhesive layer 60.

The barrier 70 may be disposed over the substrate structure. The barrier 70 may be or include a limitation structure configured to define a receiving range of an optical signal received by the optical receiver 40. In some arrangements, the limitation structure (or the barrier 70) is over the substrate structure (e.g., the substrate 10 or the combination of the substrates 10 and 20) and configured to reduce a light reflected from the limitation structure to the optical receiver 40. In some arrangements, the portion 510 (or the block structure) is disposed adjacent to the cavity C1 and configured to reflect a light from the optical emitter 30. In some arrangements, the portion 510 (or the block structure) and the barrier 70 (or the limitation structure) are disposed between the optical emitter 30 and the optical receiver 40. In some arrangements, the barrier 70 is formed of or includes an optical blocking material or a light absorbing material. In some arrangements, the barrier 70 has an optical transmittance (or a light transmittance) of no greater than about 10%, 5%, 3%, or 1%, with respect to a peak wavelength or a range of wavelengths of an optical signal (a light) emitted by the optical emitter 30. In some arrangements, the barrier 70 has an optical transmittance (or a light transmittance) of no greater than about 10%, 5%, 3%, or 1%, with respect to a peak wavelength or a range of wavelengths of an optical signal (a light) received by the optical receiver 40. The barrier 70 may be referred to as a light block structure. In some arrangements, at least a portion of the barrier 70 (or the light block structure) is over the substrate 20 and between the optical emitter 30 and the optical receiver 40. In some arrangements, the barrier 70 includes through holes C3 and C4. In some arrangements, the through hole C3 is over the optical emitter 30 and wider than the cavity C1. In some arrangements, the through hole C4 is over the optical receiver 40. In some arrangements, a roughness (e.g., a surface roughness) of a sidewall 705 of the through hole C3 is greater than a roughness (e.g., a surface roughness) of a top surface 701 of the barrier 70. In some arrangements, a roughness (e.g., a surface roughness) of a sidewall 707 of the through hole C4 is greater than a roughness (e.g., a surface roughness) of a top surface 701 of the barrier 70. In some arrangements, the barrier 70 is or includes a core substrate layer (e.g., a black core layer). In some arrangements, the barrier 70 includes a resin layer. In some arrangements, the barrier 70 is substantially free of glass fibers. In some arrangements, the barrier 70 may be omitted depending on the thickness (or the height) of the optical receiver 40. In some arrangements, the barrier 70 may be omitted when the optical receiver 40 is substantially entirely received within the cavity C2.

The protective layer 80 may be between the substrate 10 and the substrate 20. In some arrangements, the protective layer 80 is partially exposed to the cavity C1. In some arrangements, the conductive layer 110 is spaced apart from the electrical shielding element 50 by the protective layer 80. In some arrangements, the protective layer 80 directly contacts the conductive layer 110 and the electrical shielding element 50. In some arrangements, the protective layer 80 directly contacts the adhesive layer 60. The protective layer 80 may be or include a solder mask. In some arrangements, the conductive layer 110 is exposed to the cavity C1 and spaced apart from the electrical shielding element 50 by the protective layer 80.

The protective layer 81 may be between the barrier 70 and the substrate 20. The protective layer 82 may partially cover the conductive layers 10g, 110A, 101A, 102A, and 103A. The protective layers 81 and 82 may be or include solder masks.

According to some arrangements of the present disclosure, the optical emitter is disposed in a cavity defined by stacked substrates, and an electrical shielding element is adjacent to a sidewall of the cavity and between the optical emitter and the optical receiver. Therefore, crosstalk between the optical emitter and the optical receiver can be effectively prevented by the electrical shielding element. In addition, the loop height of the conductive wire for bonding the optical emitter to the substrates can be reduced by lowering the elevation of the optical emitter lowered with respect to the substrate or to the optical receiver without thinning the optical emitter. Therefore, the overall thickness of the optical package structure can be reduced, and the processing risk for thinning the optical emitter can be omitted, which is advantageous to increasing the yield.

In addition, according to some arrangements of the present disclosure, the electrical shielding element surrounds the optical emitter. Therefore, an improved optical shielding effect between the optical emitter and the optical receiver can be provided.

Moreover, according to some arrangements of the present disclosure, the horizontal portion of the electrical shielding element is disposed between the circuit structure connected to the optical emitter and the circuit structure connected to the optical receiver. Therefore, interference between the circuit structures connected can be effectively reduced.

In addition, according to some arrangements of the present disclosure, cavities are formed in the substrate without damaging, partially removing, or cutting through the conductive features (e.g., the conductive layers, the conductive vias, and the like) of the circuit structure of the substrate. As a result, even with the optical emitter and the optical receiver disposed in the cavities of the substrate, the electrical shielding element is not damaged, the coverage of the electrical shielding element is not reduced, and the original design of the circuit structure is not damages or altered. Therefore, the interference between the circuit structures connected can be effectively reduced by the electrical shielding element while the size of the optical package structure is significantly reduced.

Furthermore, in some cases the barrier for an optical package structure is formed by injecting a liquid crystal polymer (LCP) material into a mold having a predetermined shape, curing the LCP material, and removing the mold from the cured LCP material to form the barrier with the predetermined shape. Due to the processing limit of the above method and the property of the LCP material, the size of the as-formed barrier is relatively large, resulting in an increased thickness of the optical package structure. In contrast, according to some arrangements of the present disclosure, the barrier is or includes a black core layer with the through holes formed by drilling. Therefore, the black core layer may be formed with a relatively small thickness, e.g., less than about 200 μm or lower, and thus the overall thickness of the optical package structure can be further reduced, which is advantageous to the reduction of the size of the optical package structure. Moreover, the barrier (or the limitation structure) may be formed of or include a black core layer which absorbs lights instead of reflecting lights, and thus the light reflected by the barrier to the optical receiver may be reduced. Furthermore, due to the relatively large roughness of the sidewalls of the barrier (or the limitation structure) resulted from the drilling operation for forming the through holes, the light reflected by the barrier may be scattered toward outside of the cavities, and thus the light reflected by the barrier to the optical receiver may be further reduced. In addition, the barrier may be free of glass fibers. Therefore, leakage of lights resulted from the glass fibers can be further prevented.

Moreover, according to some arrangements of the present disclosure, the optical receiver is disposed over the stacked substrates, and at least partially within a cavity, and the optical receiver is further flip-chip bonded to the substrate instead of wire-bonded to the substrate. Therefore, the optical receiver at an elevation higher than that of the optical emitter with respect to the substrate can receive a relatively large amount of the optical signal, and the overall thickness of the optical package structure can be further reduced as well.

FIG. 1C is a cross-section of an optical package structure 1C in accordance with some arrangements of the present disclosure. The optical package structure 1C illustrated in FIG. 1C may be similar to that in FIGS. 1A-1B, with differences therebetween as follows.

In some arrangements, the connection portion 50R and the via portion 50V of the shielding structure is between the optical emitter 30 and the optical receiver 40. In some arrangements, portions of the circuit structure 20R connected to the optical emitter 30 and portions of the circuit structure 20R connected to the optical receiver 40 are disposed on opposite sides of the electrical shielding element 50 (or the portion 510). In some arrangements, portions of the circuit structure 10R connected to the optical emitter 30 and portions of the circuit structure 10R connected to the optical receiver 40 are disposed on opposite sides of the connection portion 50R and the via portion 50V.

According to some arrangements of the present disclosure, with the arrangements of the electrical shielding element 50, the connection portion 50R, and the via portion 50V, crosstalk between the optical emitter and the optical receiver can be effectively prevented, and the interference between the circuits connected to the optical emitter and the circuits connected to the optical receiver can be effectively reduced as well.

FIG. 1D is a cross-section of an optical package structure 1D in accordance with some arrangements of the present disclosure. The optical package structure 1D illustrated in FIG. 1D may be similar to that in FIGS. 1A-1B, with differences therebetween as follows.

In some arrangements, the optical receiver 40 includes two electrodes 410 and 420 on opposite surfaces (e.g., the surfaces 401 and 402) electrically connected to the conductive layers 210 and 220, respectively. In some arrangements, the electrode 420 is electrically connected to the conductive layer 220 through a conductive wire 92.

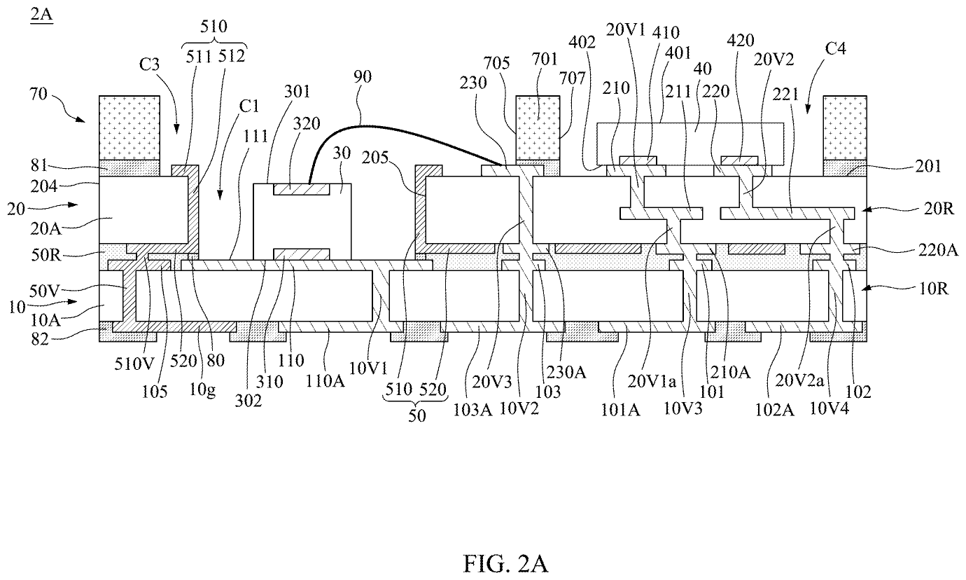

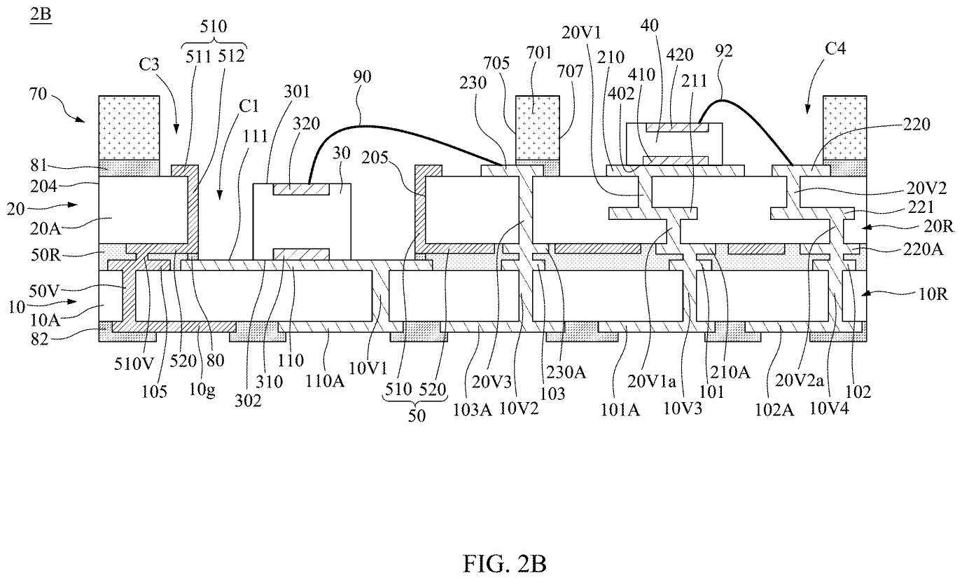

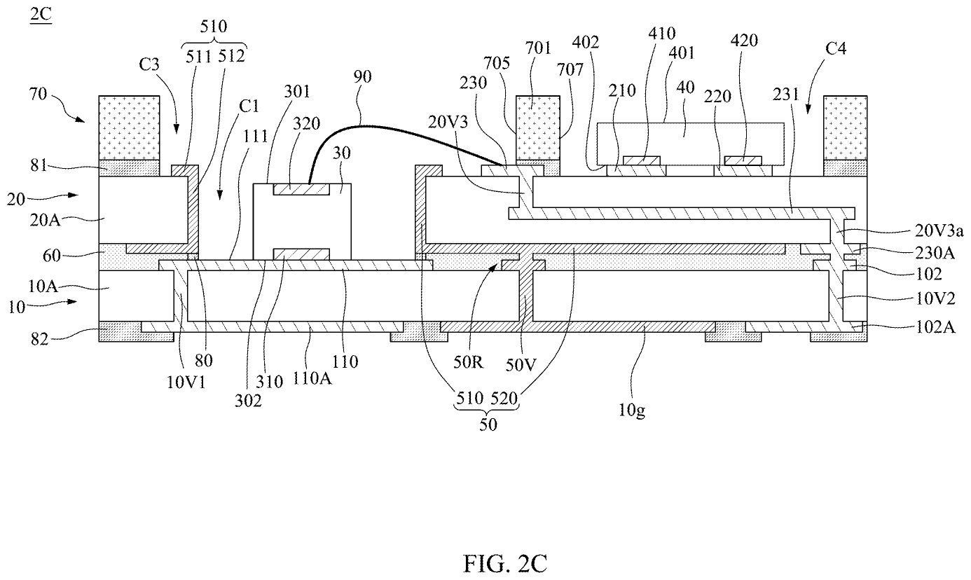

FIG. 2A is a cross-section of an optical package structure 2A in accordance with some arrangements of the present disclosure. The optical package structure 2A illustrated in FIG. 2A may be similar to that in FIGS. 1A-1B, with differences therebetween as follows.

In some arrangements, the circuit structure 20R of the substrate 20 includes conductive layers 210, 220, 230, 211, 221, 210A, 220A, and 230A and conductive vias 20V1, 20V2, 20V1a, 20V2a, and 20V3. In some arrangements, the conductive layers 210 and 220 are disposed on the surface 201. In some arrangements, the electrode 410 is electrically connected to the conductive layer 101A through the conductive layer 210, the conductive via 20V1, the conductive layer 211, the conductive via 20V1a, the conductive layer 210A, the conductive via 210V, the conductive layer 101, and the conductive via 10V3. In some arrangements, the electrode 420 is electrically connected to the conductive layer 102A through the conductive layer 220, the conductive via 20V2, the conductive layer 221, the conductive via 20V2a, the conductive layer 220A, the conductive via 220V, the conductive layer 102, and the conductive via 10V4. In some arrangements, the substrate 20 does not include a cavity C2 as shown in FIG. 1A.

FIG. 2B is a cross-section of an optical package structure in accordance with some arrangements of the present disclosure. The optical package structure 2B illustrated in FIG. 2B may be similar to that in FIG. 2A, with differences therebetween as follows.

In some arrangements, the electrode 420 of the optical receiver 40 is electrically connected to the conductive layer 220 through the conductive wire 92.

FIG. 2C is a cross-section of an optical package structure 2C in accordance with some arrangements of the present disclosure. The optical package structure 2C illustrated in FIG. 2C may be similar to that in FIG. 2A, with differences therebetween as follows.

In some arrangements, conductive layers and conductive vias of the substrate 20 that connect the conductive layers 210 and 220 to the substrate 10 are similar to those illustrate in FIG. 2A and are omitted in the cross-section illustrated in FIG. 2C. In some arrangements, the circuit structure 20R of the substrate 20 includes conductive layers 230, 231, and 230A and conductive vias 20V3 and 20V3a. In some arrangements, the electrode 320 is electrically connected to the substrate 10 through the conductive wire 90, the conductive layer 230, the conductive via 20V3, the conductive layer 231, the conductive via 20V3a, and the conductive layer 230A.

In some arrangements, the connection portion 50R and the via portion 50V of the shielding structure is between the optical emitter 30 and the optical receiver 40.

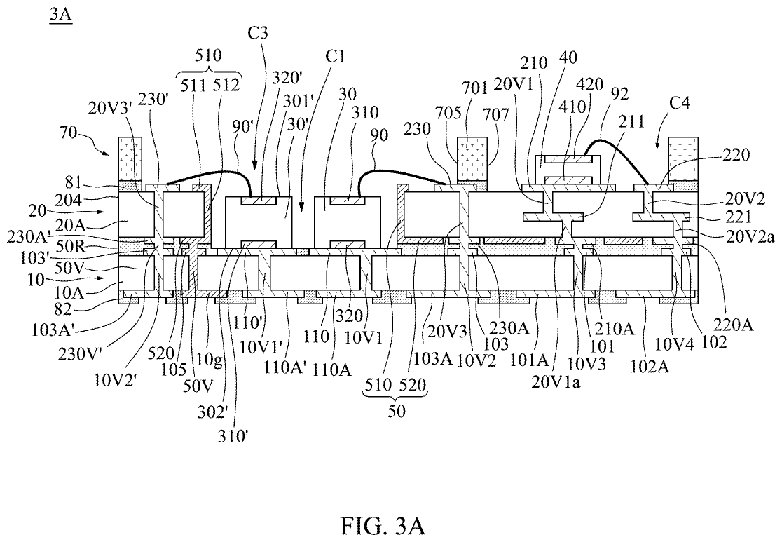

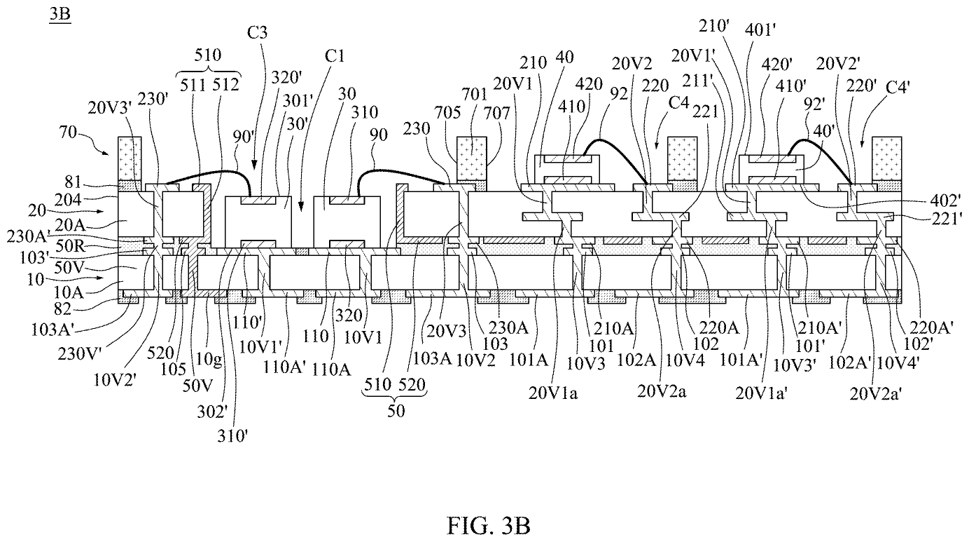

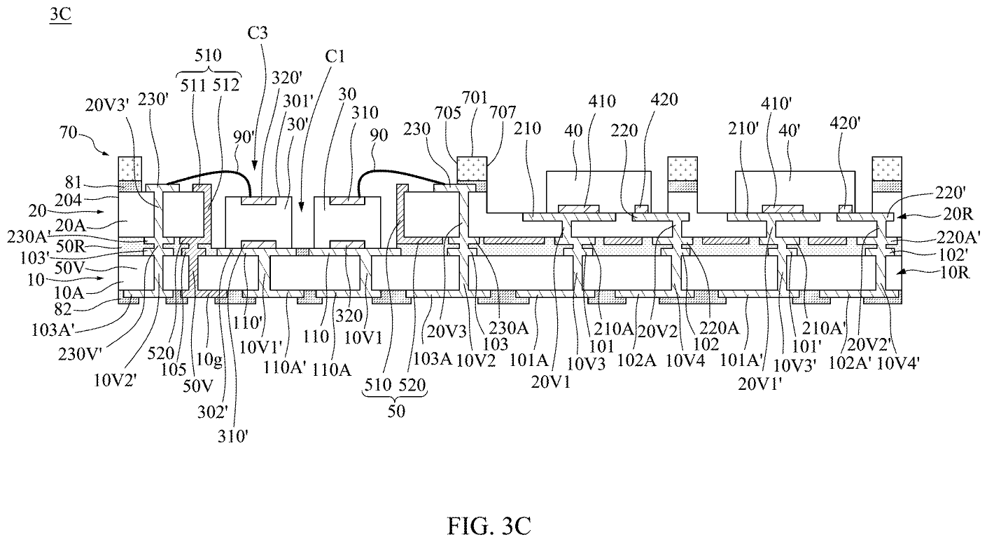

FIG. 3A is a cross-section of an optical package structure in accordance with some arrangements of the present disclosure. The optical package structure 3A illustrated in FIG. 3A may be similar to that in FIG. 2B, with differences therebetween as follows.

In some arrangements, the optical package structure 3A includes optical emitters 30 and 30′ and conductive wires 90 and 90′. In some arrangements, the circuit structure 10R of the substrate 10 further includes conductive layers 110′, 110A′, 103′, and 103A′ and conductive vias 10V1′ and 10V2′. In some arrangements, the circuit structure 20R of the substrate 20 further includes conductive layers 230′ and 230A′ and a conductive via 20V3′.

In some arrangements, the optical emitter 30′ includes two electrodes 310′ and 320′ on opposite surfaces (e.g., the surfaces 301′ and 302′) electrically connected to the conductive layer 110′ and the conductive layer 230′, respectively. In some arrangements, the electrode 310 is electrically connected to the conductive layer 110A′ through the conductive layer 110′ and the conductive via 10V1′. In some arrangements, the electrode 320′ is electrically connected to the substrate 10 through the conductive wire 90′, the conductive layer 230′, the conductive via 20V3′, and the conductive layer 230A′. In some arrangements, the electrode 320′ is electrically connected to the conductive layer 103A′ through the conductive wire 90′, the substrate 20, a conductive via 230V′, the conductive layer 103′, and the conductive via 10V2′.

FIG. 3B is a cross-section of an optical package structure 3B in accordance with some arrangements of the present disclosure. The optical package structure 3B illustrated in FIG. 3B may be similar to that in FIG. 3A, with differences therebetween as follows.

In some arrangements, the optical package structure 3B includes optical receivers 40 and 40′ and conductive wires 92 and 92′. In some arrangements, the circuit structure 10R of the substrate 10 further includes conductive layers 101′, 101A′, 102′, and 102A′ and conductive vias 10V3′ and 10V4′. In some arrangements, the circuit structure 20R of the substrate 20 further includes conductive layers 210′, 220′, 211′, 221′, 210A′, and 220A′ and conductive vias 20V1′, 20V2′, 20V1a′, and 20V2a′.

In some arrangements, the optical receiver 40′ includes electrodes 410′ and 420′. In some arrangements, the electrode 410′ is electrically connected to the conductive layer 101A′ through the conductive layer 210′, the conductive via 20V1′, the conductive layer 211′, the conductive via 20V1a′, the conductive layer 210A′, the conductive via 210V′, the conductive layer 101′, and the conductive via 10V3′. In some arrangements, the electrode 420′ is electrically connected to the conductive layer 102A′ through the conductive layer 220′, the conductive via 20V2′, the conductive layer 221′, the conductive via 20V2a′, the conductive layer 220A′, the conductive via 220V′, the conductive layer 102′, and the conductive via 10V4′.

FIG. 3C is a cross-section of an optical package structure 3C in accordance with some arrangements of the present disclosure. The optical package structure 3C illustrated in FIG. 3C may be similar to that in FIG. 3B, with differences therebetween as follows.

In some arrangements, the substrate 20 includes cavities C2 and C2′ for accommodating the optical receivers 40 and 40′, respectively. In some arrangements, the barrier 70 includes through holes C4 and C4′ each over and connected to the cavities C2 and C2′, respectively.

In some arrangements, the optical receivers 40 and 40′ are flip-chip bonded to the substrate 20. In some arrangements, the electrode 410′ of the optical receiver 40′ is electrically connected to the conductive layer 101A′ through the conductive layer 210′, the conductive via 20V1′, the conductive layer 210A′, the conductive via 210V′, the conductive layer 101′, and the conductive via 10V3′. In some arrangements, the electrode 420′ of the optical receiver 40′ is electrically connected to the conductive layer 102A′ through the conductive layer 220′, the conductive via 20V2′, the conductive layer 220A′, the conductive via 220V′, the conductive layer 102′, and the conductive via 10V4′.

It should be noted that the number of optical emitters and the number of the optical receivers in an optical package structure may vary according to actual applications and are not limited to the above examples illustrated in FIGS. 3A-3C. According to some arrangements of the present disclosure, the cavity may accommodate one or more optical emitters and/or one or more optical receivers. Therefore, the design flexibility is increased, and the device performance can be optimized simply by adjusting the number of the optical emitters and the number of the optical receivers in the cavities.

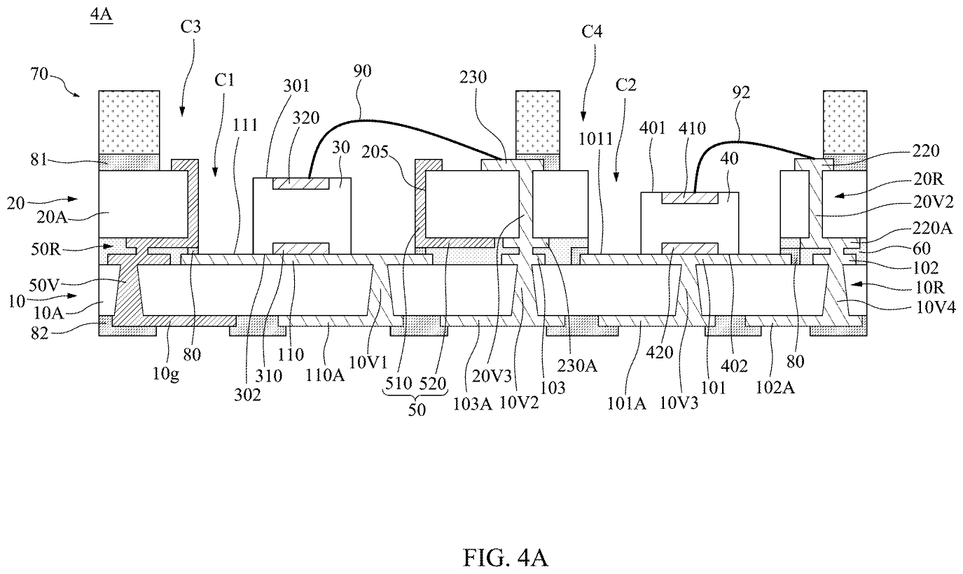

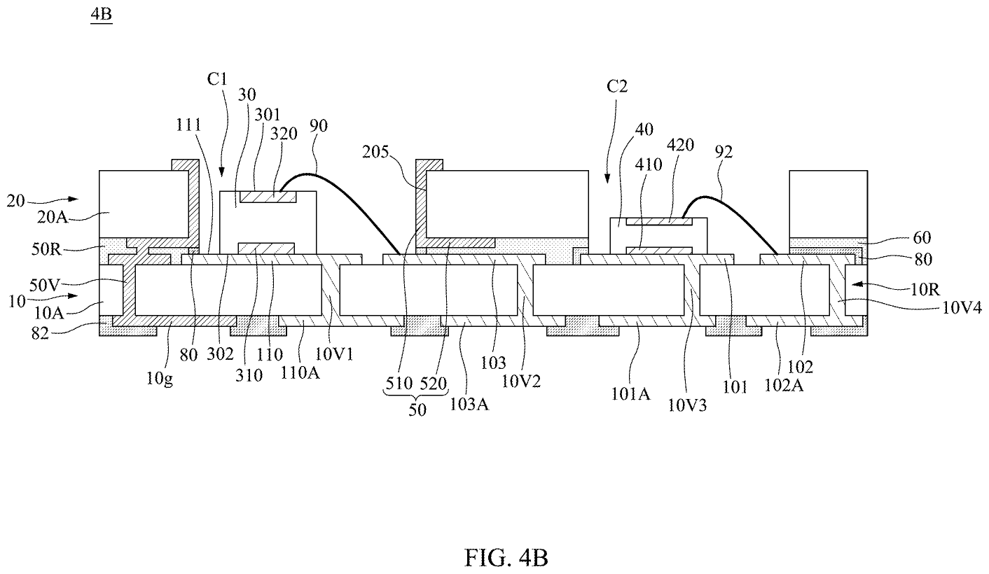

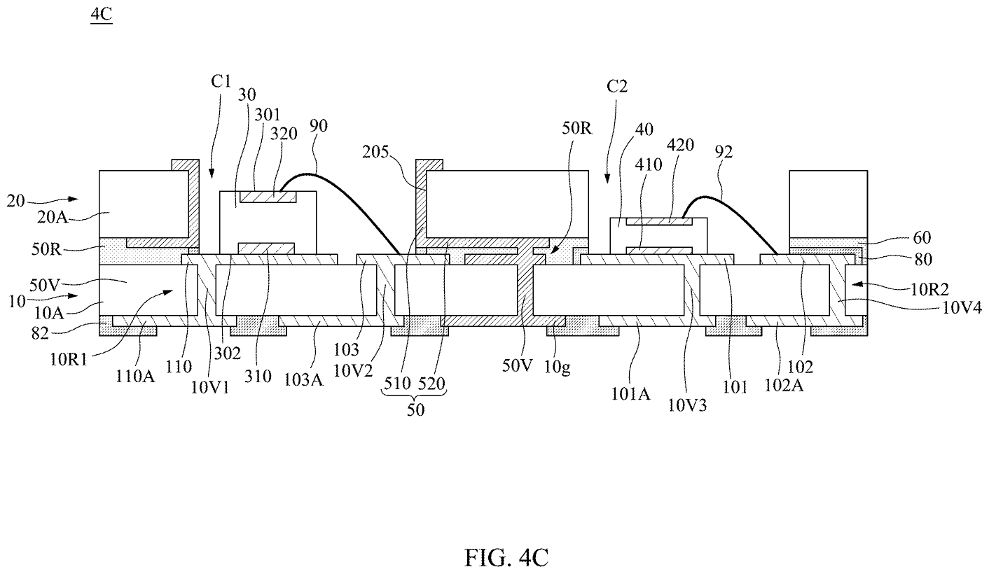

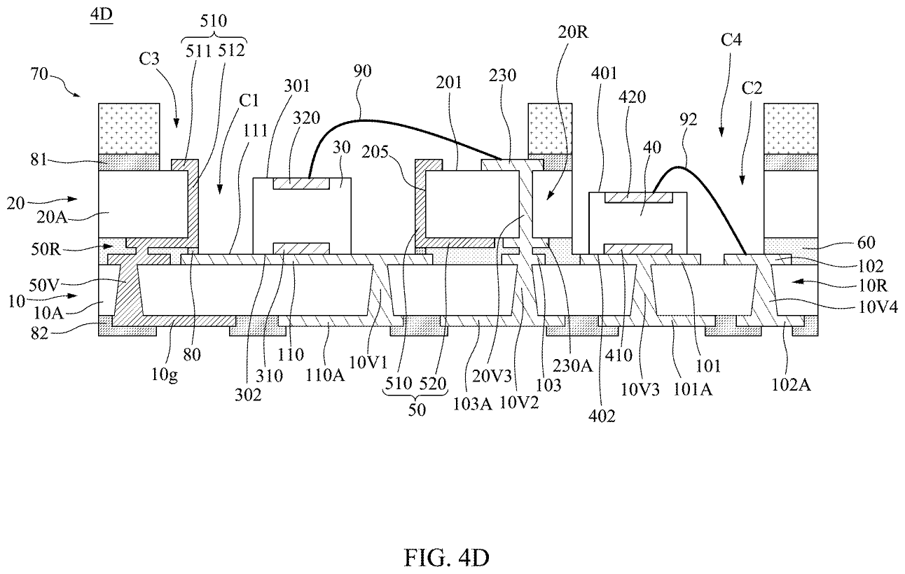

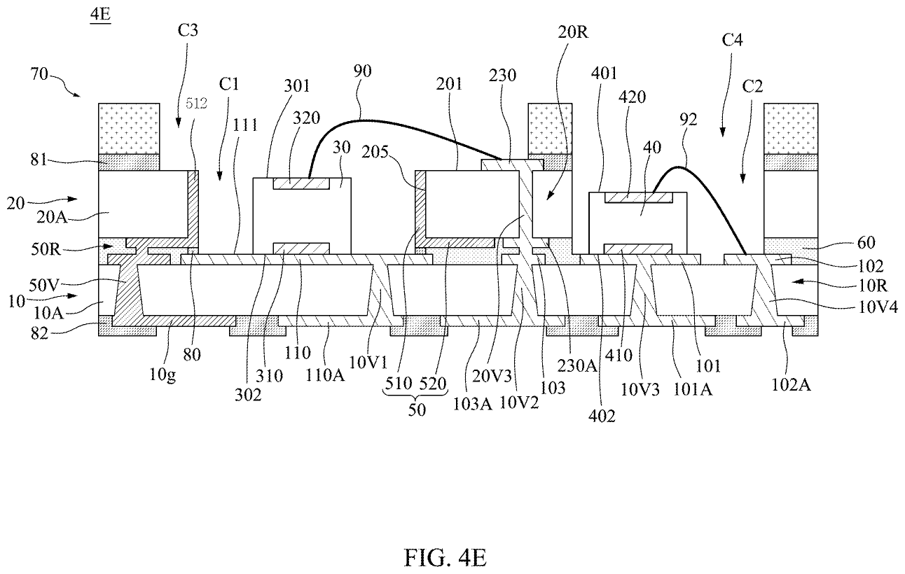

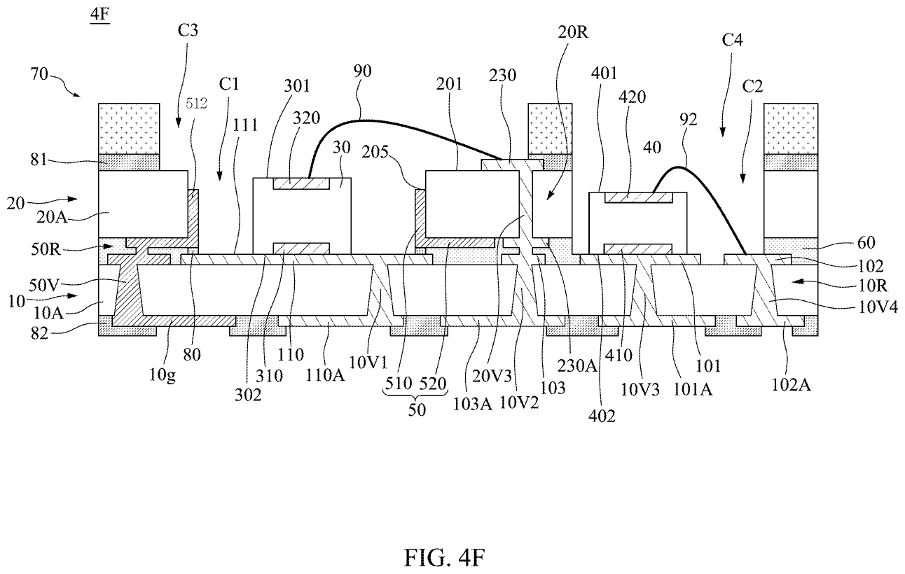

FIG. 4A is a cross-section of an optical package structure 4A in accordance with some arrangements of the present disclosure. The optical package structure 4A illustrated in FIG. 4A may be similar to that in FIGS. 1A-1B, with differences therebetween as follows.

In some arrangements, a portion of a top surface (e.g., a surface 1011) of the substrate 10 is exposed to the cavity C2. In some arrangements, a portion of the surface 1011 of the conductive layer 101 of the substrate 10 is exposed to the cavity C2. In some arrangements, the adhesive layer 60 is partially exposed to the cavity C2. In some arrangements, the protective layer 80 is partially exposed to the cavity C2.

In some arrangements, the optical receiver 40 is entirely in the cavity C2. In some arrangements, the electrode 410 of the optical receiver 40 is electrically connected to the conductive layer 101A through the conductive layer 101 and the conductive via 10V3.

In some arrangements, the base layer 20A may be or include a black core layer. The substrate 10 may be referred to as a substrate structure, and the combination of the base layer 20A and the barrier 70 may be referred to as a limitation structure over the substrate structure and configured to reduce lights reflected from the limitation structure to the optical receiver 40. In some arrangements, the base layer 20A is formed of or includes a black core layer which absorbs lights instead of reflecting lights, and thus the light reflected by the barrier 70 to the optical receiver 40 may be reduced. The substrate structure (e.g., the substrate 10) and the limitation structure may collectively define a cavity C1 for accommodating the optical emitter 30, and the portion 510 (or the block structure) is disposed adjacent to the cavity C1 and configured to reflect a light from the optical emitter 30. In some arrangements, the portion 510 (or the block structure) and the combination of the base layer 20A and the barrier 70 (or the limitation structure) are disposed between the optical emitter 30 and the optical receiver 40. According to some arrangements of the present disclosure, with the base layer 20A and the barrier 70 both formed of black core layers, the overall thickness can be reduced, and the crosstalk of optical signals between the optical emitter and the optical receiver can be further effectively prevented.

FIG. 4B is a cross-section of an optical package structure 4B in accordance with some arrangements of the present disclosure. The optical package structure 4B illustrated in FIG. 4B may be similar to that in FIG. 4A, with differences therebetween as follows.

In some arrangements, the electrode 420 of the optical receiver 40 is electrically connected to the conductive layer 102A through the conductive wire 92, the conductive layer 102, and the conductive via 10V4. In some arrangements, the optical package structure 4B does not include a barrier 70 illustrated in FIG. 4A. In some arrangements, the barrier 70 may be omitted when the optical receiver 40 and the conductive wire 92 substantially entirely received within the cavity C2. In some arrangements, the base layer 20A may be or include a black core layer.

The substrate 10 may be referred to as a substrate structure, and the base layer 20A may be referred to as a limitation structure over the substrate structure and configured to reduce lights reflected from the limitation structure to the optical receiver 40. The substrate structure (e.g., the substrate 10) and the limitation structure may collectively define a cavity C1 for accommodating the optical emitter 30, and the portion 510 (or the block structure) is disposed adjacent to the cavity C1 and configured to reflect a light from the optical emitter 30. In some arrangements, the portion 510 (or the block structure) and the base layer 20A (or the limitation structure) are disposed between the optical emitter 30 and the optical receiver 40. According to some arrangements of the present disclosure, with the base layer 20A formed of a black core layer and the barrier 70 is removed, the overall thickness of the optical package structure can be further reduced, and the crosstalk between optical signals of the optical emitter and the optical receiver can be effectively prevented.

FIG. 4C is a cross-section of an optical package structure 4C in accordance with some arrangements of the present disclosure. The optical package structure 4C illustrated in FIG. 4C may be similar to that in FIG. 4B, with differences therebetween as follows.

In some arrangements, the connection portion 50R and the via portion 50V of the shielding structure is between the optical emitter 30 and the optical receiver 40. In some arrangements, the substrate 10 includes a circuit structure 10R1 electrically connected to the optical emitter 30 and a circuit structure 10R2 electrically connected to the optical receiver 40. In some arrangements, the circuit structure 10R1 includes the conductive layers 110, 110A, 103, and 103A and the conductive vias 10V1 and 10V2. In some arrangements, the circuit structure 10R2 includes the conductive layers 101, 101A, 102, and 102A and conductive vias 10V3 and 10V4. In some arrangements, the via portion 50V is between the circuit structure 10R1 and the circuit structure 10R2.

According to some arrangements of the present disclosure, with the arrangements of the electrical shielding element 50, the connection portion 50R, and the via portion 50V, crosstalk between the optical emitter and the optical receiver can be effectively prevented, and the interference between the circuit structure connected to the optical emitter and the circuit structure connected to the optical receiver can be effectively reduced as well.

FIG. 4D is a cross-section of an optical package structure 4D in accordance with some arrangements of the present disclosure. The optical package structure 4D illustrated in FIG. 4D may be similar to that in FIG. 4A, with differences therebetween as follows.

In some arrangements, the electrode 420 of the optical receiver 40 is electrically connected to the conductive layer 102A through the conductive wire 92, the conductive layer 102, and the conductive via 10V4. In some arrangements, the cavity C2 (or the recess) is connected to and substantially aligned with the through hole C4 of the barrier 70. In some arrangements, the cavity C2 and the through hole C4 are formed by a single operation.

FIG. 4E is a cross-section of an optical package structure 4E in accordance with some arrangements of the present disclosure. The optical package structure 4E illustrated in FIG. 4E may be similar to that in FIG. 4D, with differences therebetween as follows.

In some arrangements, the electrical shielding element 50 includes a vertical part 512 without an extension covering the surface 201 of the substrate 20. In some arrangements, a top surface of the vertical part 512 is substantially aligned with or coplanar with the surface 201 of the substrate 20.

FIG. 4F is a cross-section of an optical package structure 4F in accordance with some arrangements of the present disclosure. The optical package structure 4F illustrated in FIG. 4F may be similar to that in FIG. 4D, with differences therebetween as follows.

In some arrangements, the electrical shielding element 50 includes a vertical part 512 without an extension covering the surface 201 of the substrate 20. In some arrangements, a top surface of the vertical part 512 is lower than the surface 201 of the substrate 20.

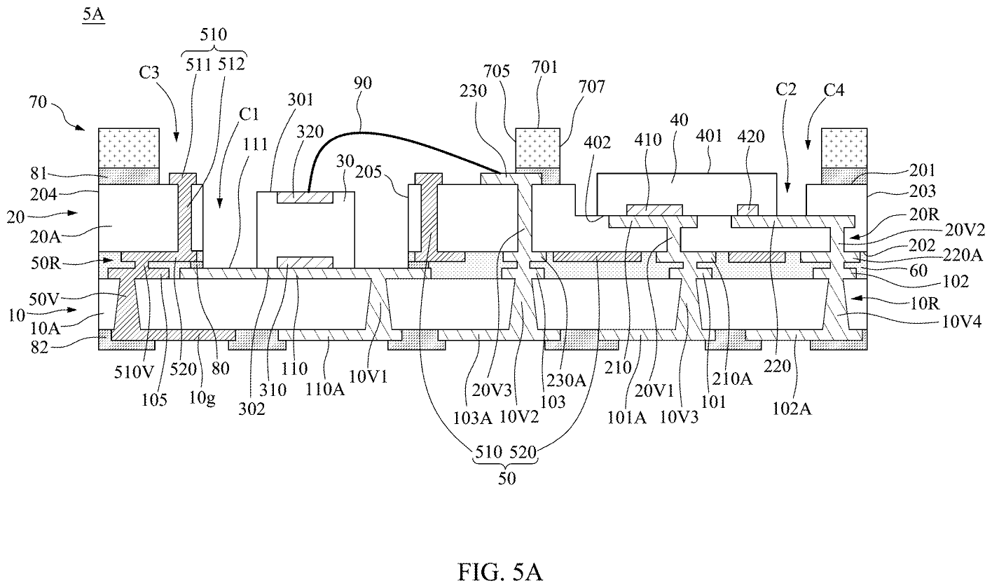

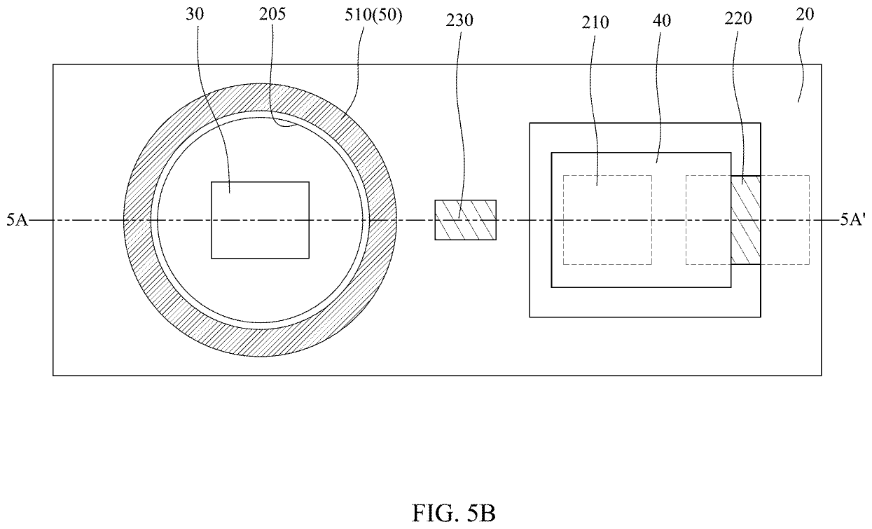

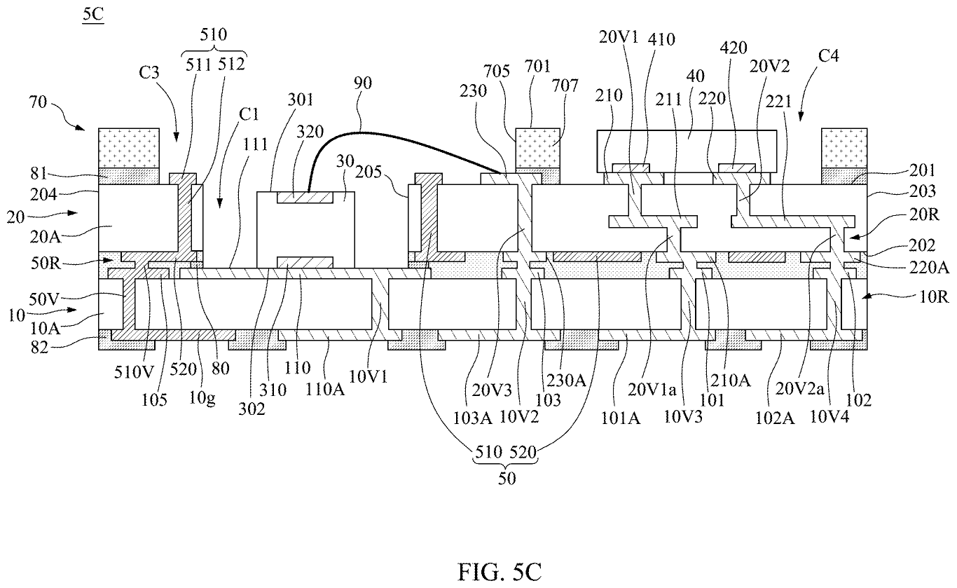

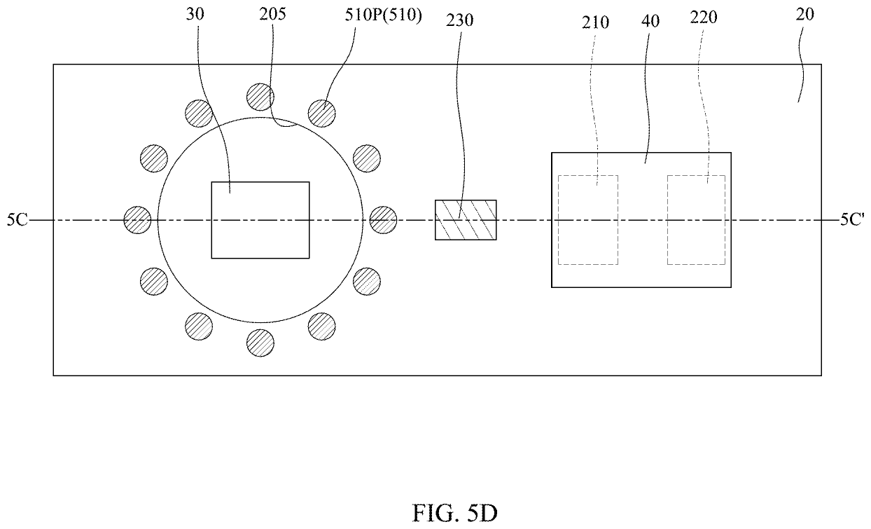

FIG. 5A is a cross-section of an optical package structure 5A in accordance with some arrangements of the present disclosure. FIG. 5B is a top view of an optical package structure 5A in accordance with some arrangements of the present disclosure. In some arrangements, FIG. 5A is a cross-section along a line 5A-5A′ in FIG. 5B. The optical package structure 5A illustrated in FIGS. 5A-5B may be similar to that in FIGS. 1A-1B, with differences therebetween as follows.

In some arrangements, the electrical shielding element 50 (or the portion 510) is embedded in the substrate 20 and spaced apart from the sidewall 205 of the cavity C1. In some arrangements, the electrical shielding element 50 (or the portion 510) is embedded in the substrate 20 and spaced apart from the sidewall 205 of the cavity C1 by a portion of the substrate 20 (or a portion of the base layer 20A). In some arrangements, referring to FIG. 5B, the portion 510 surrounds the optical emitter 30 from a top view perspective.

According to some arrangements of the present disclosure, the electrical shielding element 50 (or the portion 510) is embedded in the substrate 20 and spaced apart from the sidewall 205 of the cavity C1, and thus it can prevent the electrical shielding element 50 (e.g., the metal material of the electrical shielding element 50) from affecting the light-emitting angle of the optical emitter 30.

FIG. 5C is a cross-section of an optical package structure 5C in accordance with some arrangements of the present disclosure. FIG. 5D is a top view of an optical package structure 5C in accordance with some arrangements of the present disclosure. In some arrangements, FIG. 5C is a cross-section along a line 5C-5C′ in FIG. 5D. The optical package structure 5C illustrated in FIGS. 5C-5D may be similar to that in FIGS. 1A-1B, with differences therebetween as follows.

In some arrangements, the electrical shielding element 50 (or the portion 510) is embedded in the substrate 20 and spaced apart from the sidewall 205 of the cavity C1. In some arrangements, the electrical shielding element 50 (or the portion 510) is embedded in the substrate 20 and spaced apart from the sidewall 205 of the cavity C1 by a portion of the substrate 20 (or a portion of the base layer 20A). In some arrangements, referring to FIG. 5D, the portion 510 surrounds the optical emitter 30 from a top view perspective. In some arrangements, the portion 510 further includes a plurality of pillars 510P (or vias) surrounding the optical emitter 30.

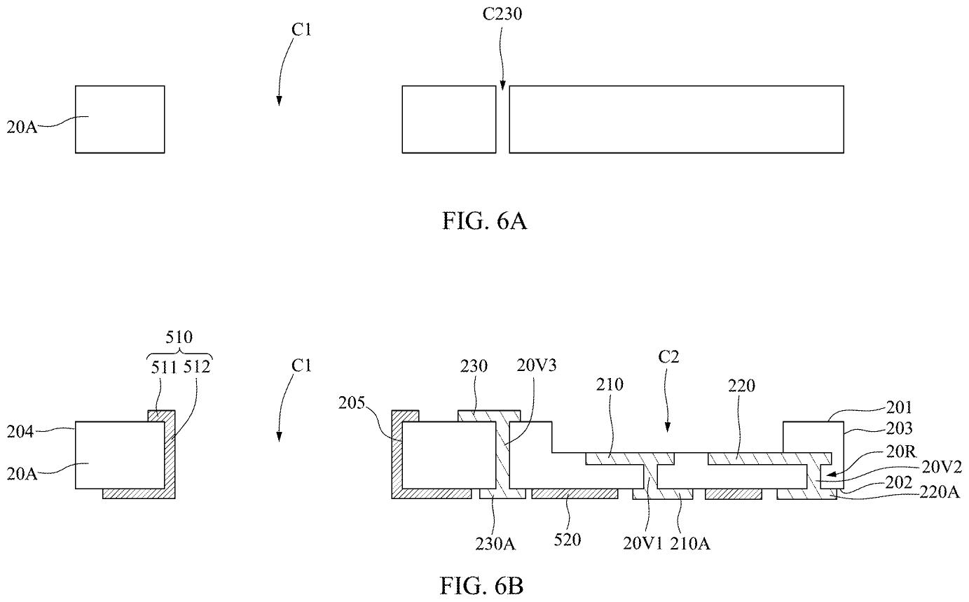

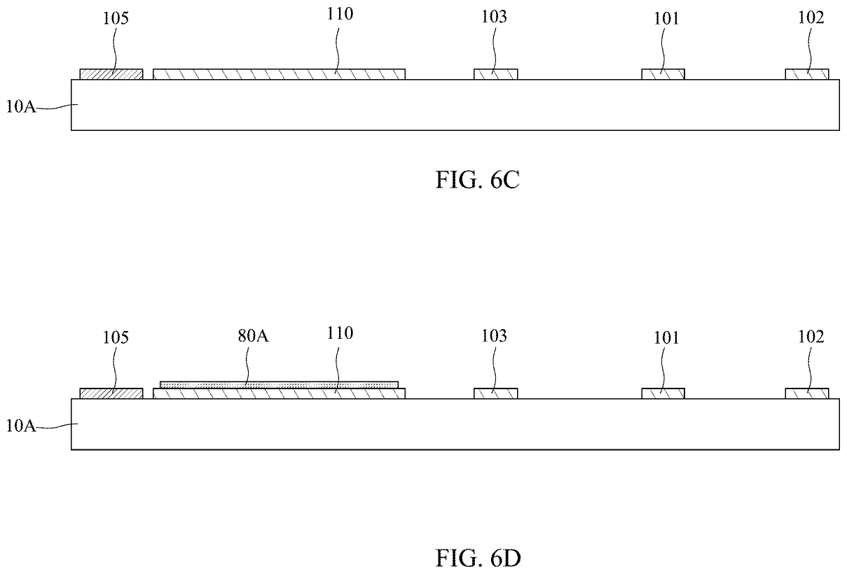

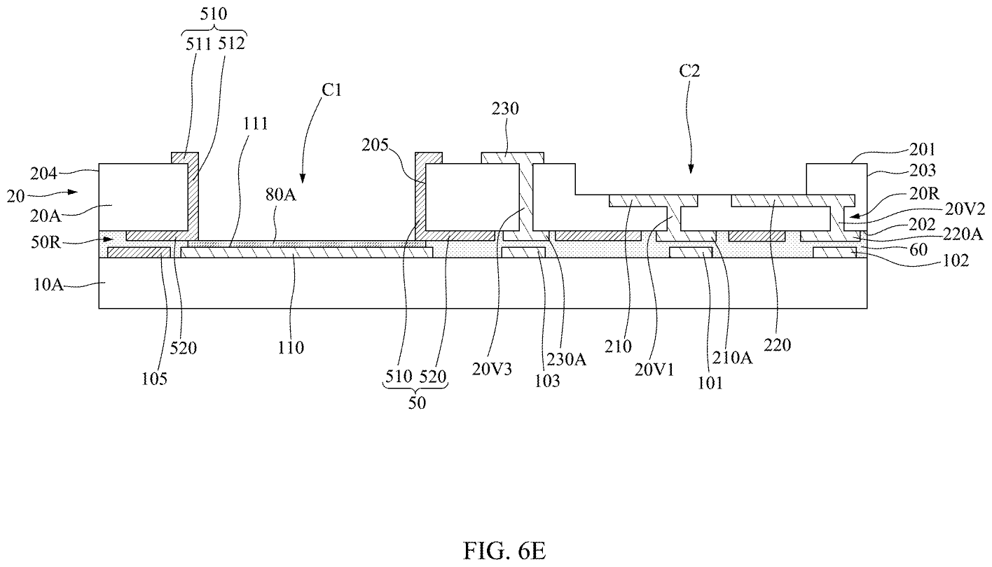

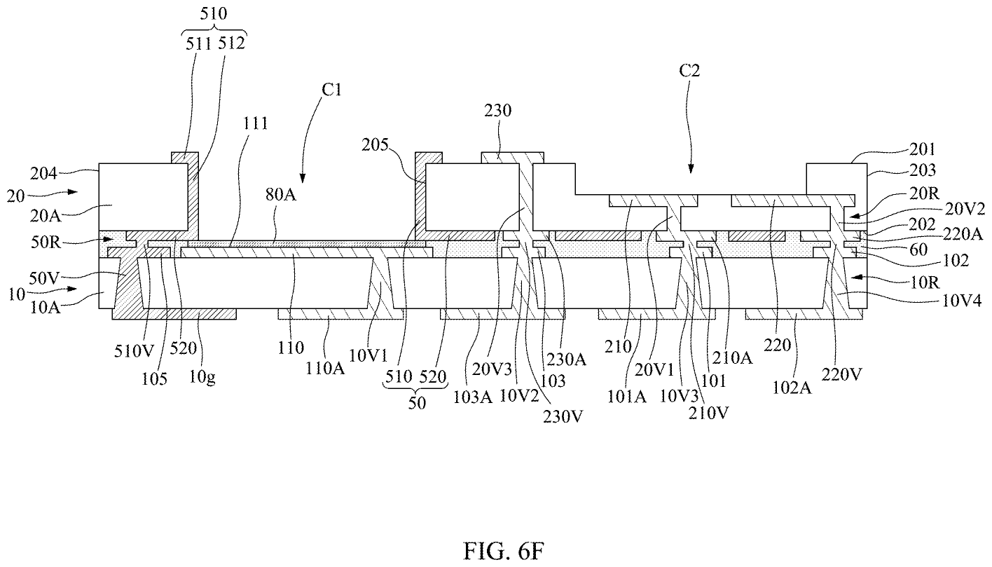

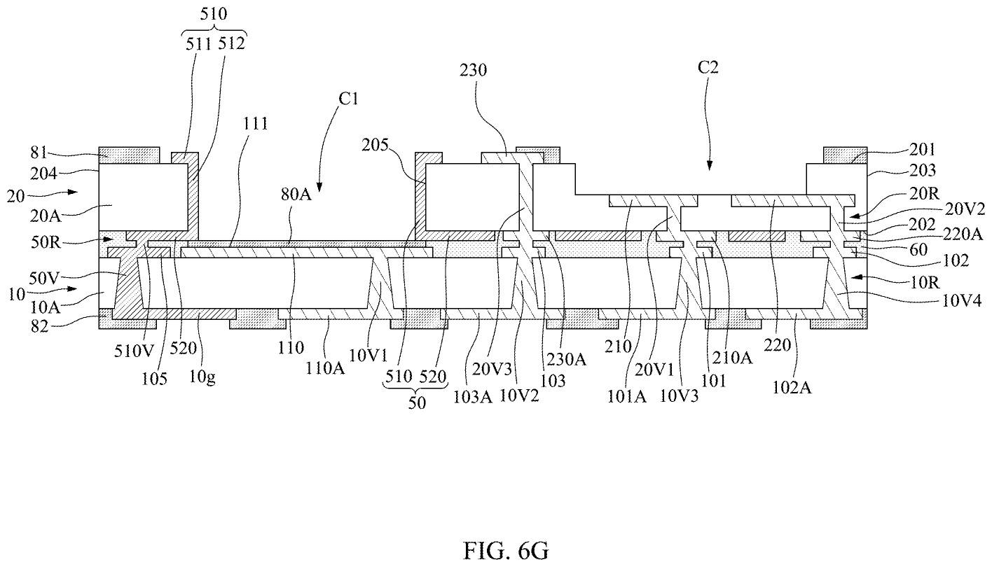

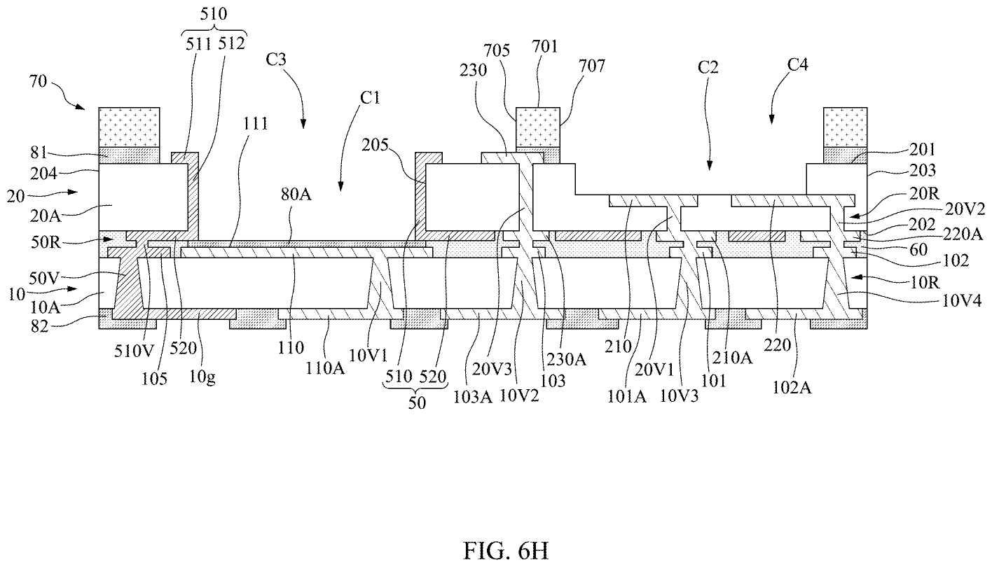

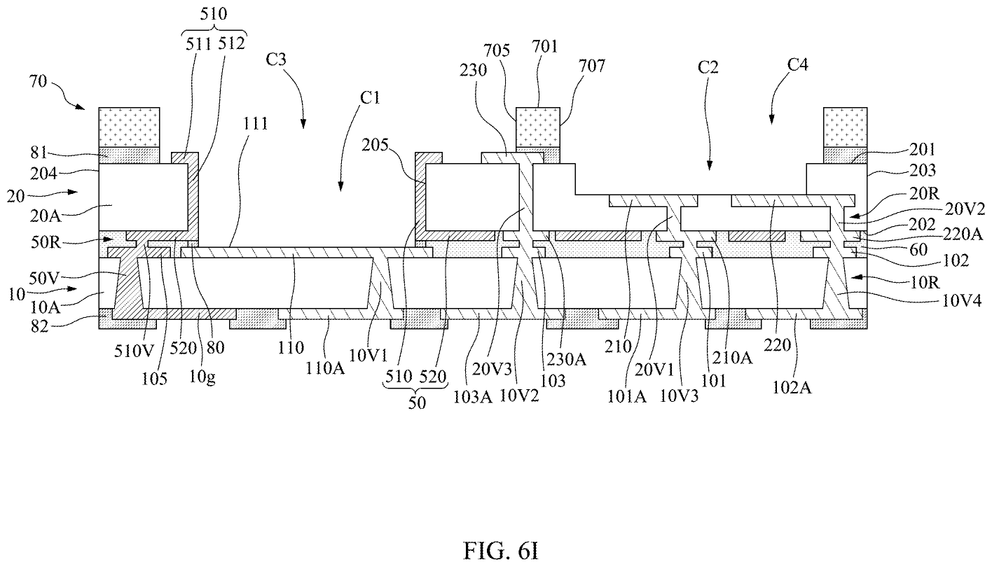

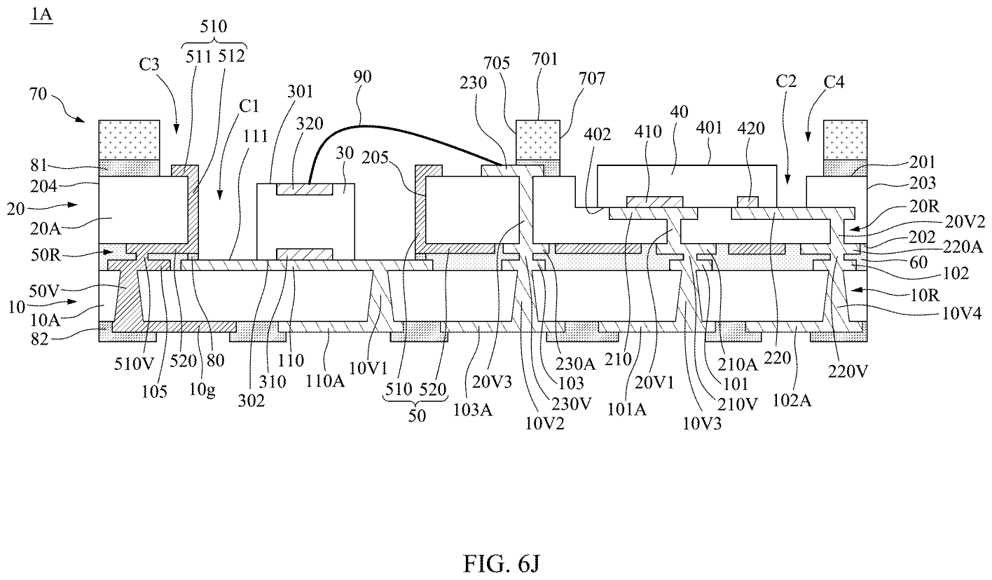

FIG. 6A, FIG. 6B, FIG. 6C, FIG. 6D, FIG. 6E, FIG. 6F, FIG. 6G, FIG. 6H, FIG. 6I, and FIG. 6J illustrate various stages of an exemplary method for manufacturing an optical package structure 1A in accordance with some arrangements of the present disclosure.

Referring to FIG. 6A, a base layer 20A may be provided, and a cavity C1 and a through hole C230 may be formed in the base layer 20A. In some arrangements, the cavity C1 and the through hole C230 may be formed by laser drilling, etching, or other suitable technique. In some arrangements, the base layer 20A may be or include an insulating material or a dielectric material.

Referring to FIG. 6B, a cavity C2 may be formed in the base layer 20A, and a circuit structure 20R and an electrical shielding element 50 may be formed. In some arrangements, the circuit structure 20R includes conductive layers 210, 220, 230, 210A, 220A, and 230A and conductive vias 20V1, 20V2, and 20V3. In some arrangements, the electrical shielding element 50 includes a portion 510 including a vertical part 512 on a sidewall of the cavity C1 and an extension 511 partially covering a surface 201 (or the top surface) of the base layer 20A. In some arrangements, the electrical shielding element 50 further includes a portion 520 partially covering a surface 202 (or the bottom surface) of the base layer 20A. The conductive layers 210, 220, 230, 210A, 220A, and 230A, the conductive vias 20V1, 20V2, and 20V3, and the electrical shielding element 50 may be formed by plating.

Referring to FIG. 6C, a base layer 10A may be provided, and conductive layers 101, 102, 103, 105, and 110 may be formed on the base layer 10A. In some arrangements, the base layer 10A may be or include an insulating material or a dielectric material. In some arrangements, the conductive layers 101, 102, 103, 105, and 110 may be formed by deposition or plating.

Referring to FIG. 6D, a protective layer 80A may be formed on the conductive layer 110. In some arrangements, the protective layer 80A may be or include a solder mask.

Referring to FIG. 6E, the base layer 20A with the electrical shielding element 50 and the circuit structure 20R may be adhered to the base layer 10A through an adhesive layer 60. In some arrangements, the conductive layer 110 is protected by the protective layer 80A from being exposed to the cavity C1. In some arrangements, the adhesive layer 60 is disposed on the base layer 10A, the base layer 20A is then laminated onto the adhesive layer 60, and then the adhesive layer 60 may be heated until it softens and adheres the base layer 20A to the base layer 10A. As a result, the as-formed adhesive layer 60 may be filled in the spaces between the base layer 20A and the base layer 10A. In some arrangements, the adhesive layer 60 may be or include a hot melt adhesive. In some arrangements, the adhesive layer 60 may include an insulating adhesive sheet, a polypropylene (PP) film, a liquid-phase insulating adhesive, or a combination thereof. According to some arrangements of the present disclosure, the protective layer 80A can prevent the adhesive layer 60 from flowing over the conductive layer 110, and thus a sufficient contact surface of the conductive layer 110 may be provided for the optical emitter 30 which will be connected thereto in subsequent operations.

Referring to FIG. 6F, a plurality of conductive vias (e.g., conductive vias 10V1, 10V2, 10V3, 10V4, 510V, 210V, 220V, and 230V and a via portion 50V) and conductive layers 101A, 102A, 103A, 10g, and 110A may be formed, so as to form a circuit structure 10R. In some arrangements, the conductive vias and the conductive layers of the circuit structure 10R may be formed by deposition or plating.

Referring to FIG. 6G, protective layers 81 and 82 may be formed. In some arrangements, the protective layer 81 is formed on the surface 201 and partially covering the conductive layer 230. In some arrangements, the protective layer 82 is formed to partially cover the conductive layers 101A, 102A, 103A, 10g, and 110A. In some arrangements, the protective layers 81 and 82 may be or include solder masks.

Referring to FIG. 6H, a barrier 70 including through holes C3 and C4 may be formed over the substrate 20. In some arrangements, the barrier 70 may be laminated to the protective layer 81.

Referring to FIG. 6I, a portion of the protective layer 80A exposed to the cavity C1 may be removed to form a protective layer 80. In some arrangements, the conductive layer 110 is exposed by the protective layer 80 and exposed to the cavity C1.

Referring to FIG. 6J, an optical emitter 30 may be disposed in the cavity C1, and an optical receiver 40 may be disposed in the cavity C2. As such, the optical package structure 1A is formed.

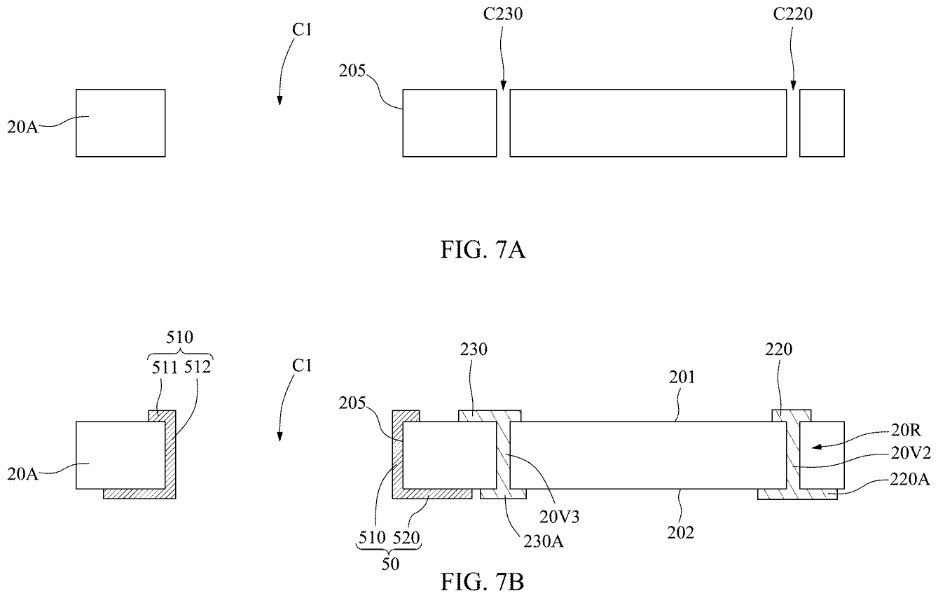

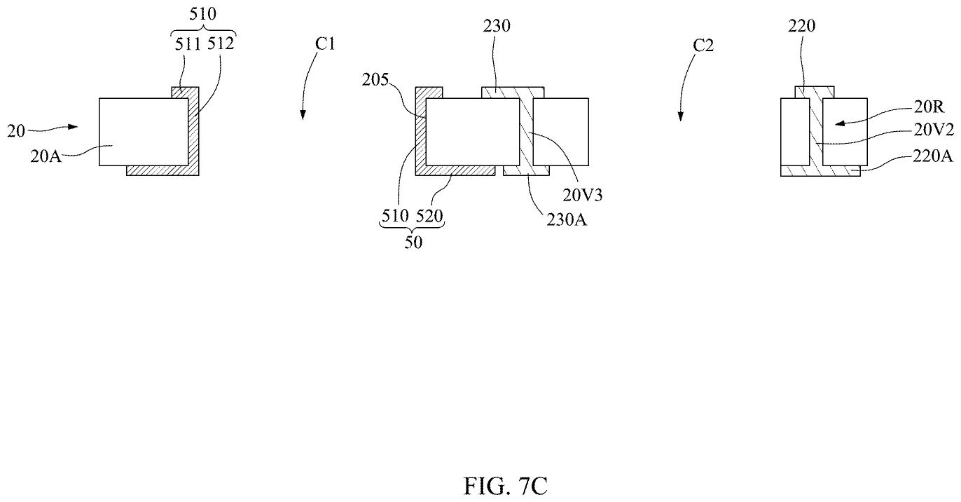

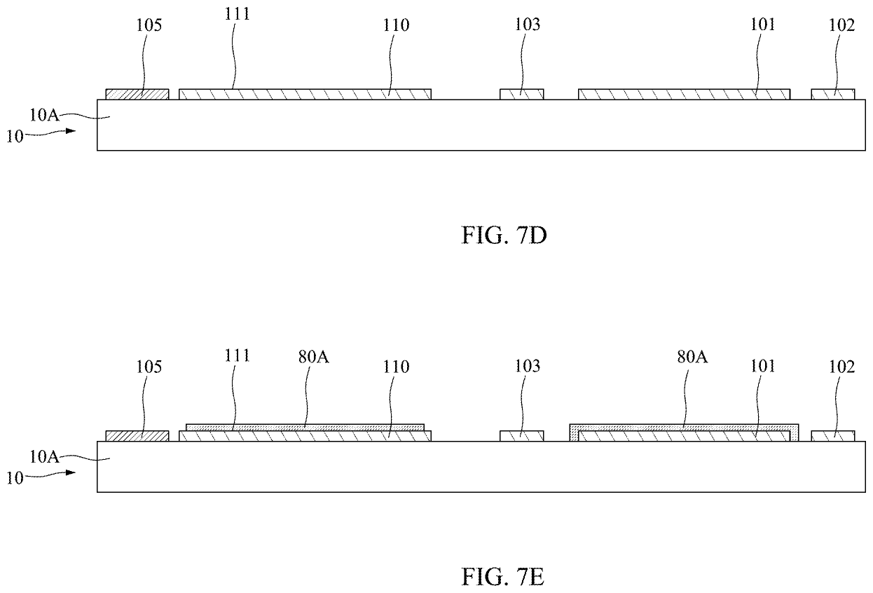

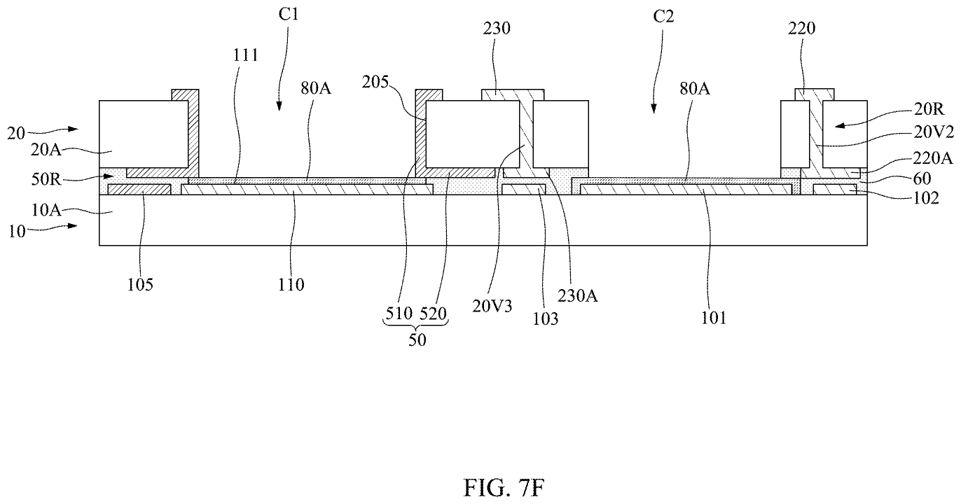

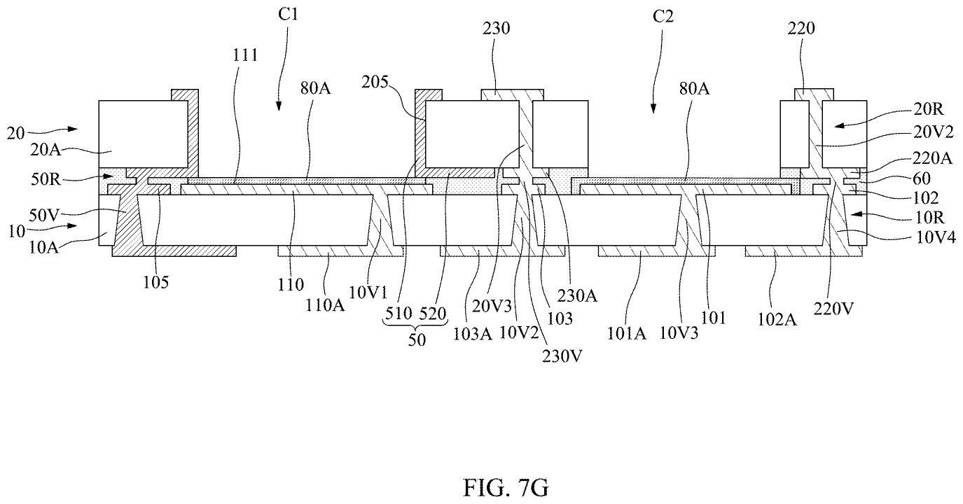

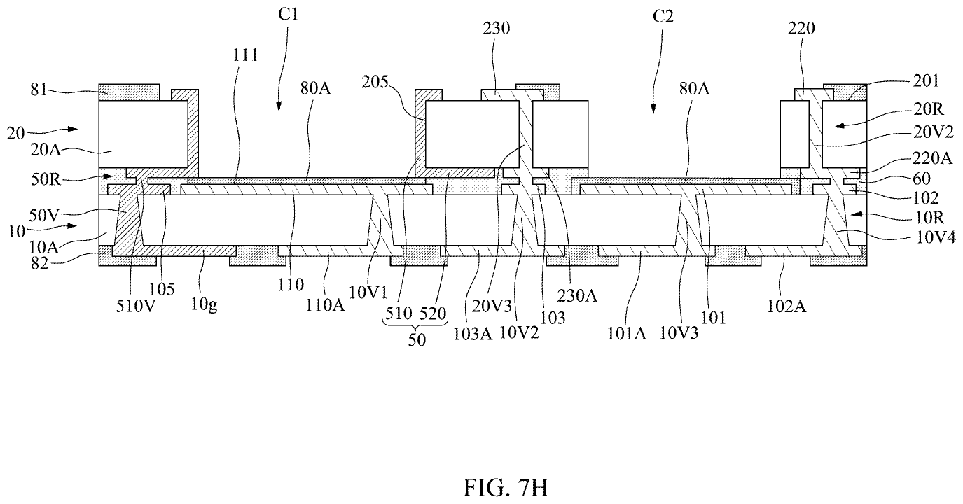

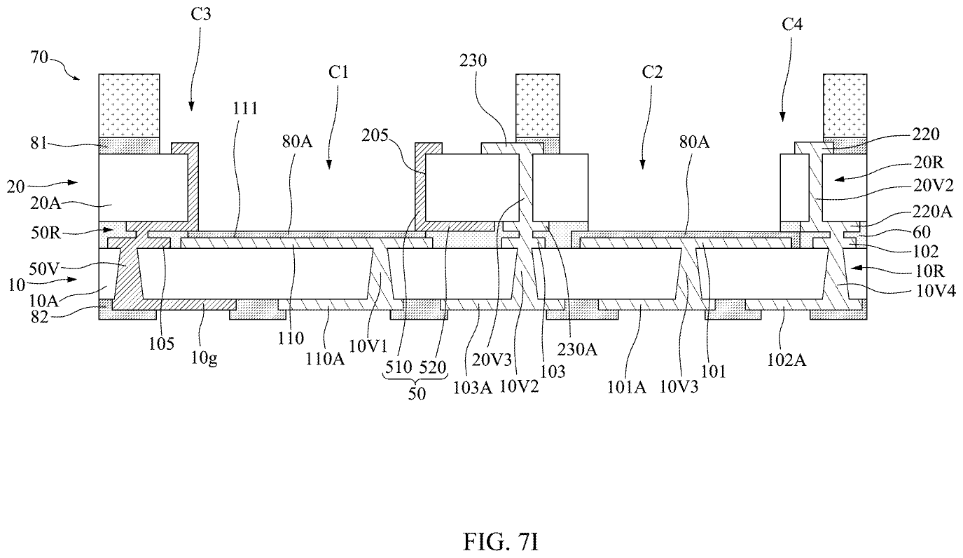

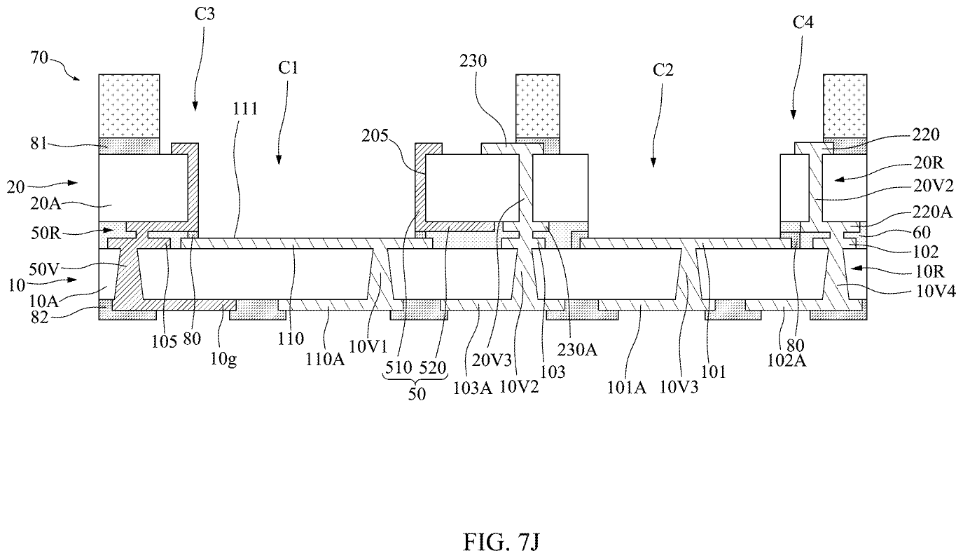

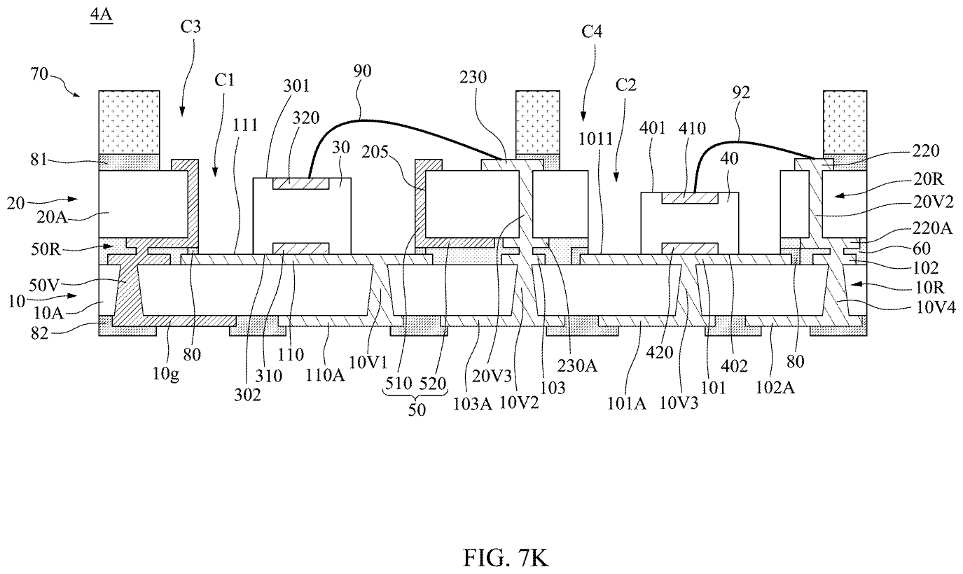

FIG. 7A, FIG. 7B, FIG. 7C, FIG. 7D, FIG. 7E, FIG. 7F, FIG. 7G, FIG. 7H, FIG. 7I, FIG. 7J, and FIG. 7K illustrate various stages of an exemplary method for manufacturing an optical package structure 4A in accordance with some arrangements of the present disclosure.

Referring to FIG. 7A, a base layer 20A may be provided, and a cavity C1 and through holes C220 and C230 may be formed in the base layer 20A. In some arrangements, the cavity C1 and the through holes C220 and C230 may be formed by laser drilling, etching, or other suitable technique. In some arrangements, the base layer 20A may be or include an insulating material or a dielectric material.

Referring to FIG. 7B, a circuit structure 20R and an electrical shielding element 50 may be formed. In some arrangements, the circuit structure 20R includes conductive layers 220, 230, 220A, and 230A and conductive vias 20V2 and 20V3. In some arrangements, the electrical shielding element 50 includes a portion 510 including a vertical part 512 on a sidewall of the cavity C1 and an extension 511 partially covering a surface 201 (or the top surface) of the base layer 20A. In some arrangements, the electrical shielding element 50 further includes a portion 520 partially covering a surface 202 (or the bottom surface) of the base layer 20A. The conductive layers 220, 230, 220A, and 230A, the conductive vias 20V2 and 20V3, and the electrical shielding element 50 may be formed by plating.

Referring to FIG. 7C, a cavity C2 may be formed in the base layer 20A.

Referring to FIG. 7D, a base layer 10A may be provided, and conductive layers 101, 102, 103, 105, and 110 may be formed on the base layer 10A. In some arrangements, the base layer 10A may be or include an insulating material or a dielectric material. In some arrangements, the conductive layers 101, 102, 103, 105, and 110 may be formed by deposition or plating.

Referring to FIG. 7E, protective layers 80A may be formed on the conductive layers 101 and 110. In some arrangements, the protective layers 80A may be or include solder masks.

Referring to FIG. 7F, the base layer 20A with the electrical shielding element 50 and the circuit structure 20R may be adhered to the base layer 10A through an adhesive layer 60. In some arrangements, the conductive layer 110 is protected by the protective layer 80A from being exposed to the cavity C1, and the conductive layer 101 is protected by the protective layer 80A from being exposed to the cavity C2. In some arrangements, the adhesive layer 60 is disposed on the base layer 10A, the base layer 20A is then laminated onto the adhesive layer 60, and then the adhesive layer 60 may be heated until it softens and adheres the base layer 20A to the base layer 10A. As a result, the as-formed adhesive layer 60 may be filled in the spaces between the base layer 20A and the base layer 10A. In some arrangements, the adhesive layer 60 may be or include a hot melt adhesive. In some arrangements, the adhesive layer 60 may include an insulating adhesive sheet, a polypropylene (PP) film, a liquid-phase insulating adhesive, or a combination thereof. According to some arrangements of the present disclosure, the protective layer 80As can prevent the adhesive layer 60 from flowing over the conductive layers 101 and 110, and thus sufficient contact surfaces of the conductive layers 101 and 110 may be provided for the optical emitter 30 and the optical receiver 40 which will be connected thereto in subsequent operations.

Referring to FIG. 7G, a plurality of conductive vias (e.g., conductive vias 10V1, 10V2, 10V3, 10V4, 510V, 220V, and 230V and a via portion 50V) and conductive layers 101A, 102A, 103A, 10g, and 110A may be formed, so as to form a circuit structure 10R. In some arrangements, the conductive vias and the conductive layers of the circuit structure 10R may be formed by deposition or plating.

Referring to FIG. 7H, protective layers 81 and 82 may be formed. In some arrangements, the protective layer 81 is formed on the surface 201 and partially covering the conductive layers 220 and 230. In some arrangements, the protective layer 82 is formed to partially cover the conductive layers 101A, 102A, 103A, 10g, and 110A. In some arrangements, the protective layers 81 and 82 may be or include solder masks.

Referring to FIG. 7I, a barrier 70 including through holes C3 and C4 may be formed over the substrate 20. In some arrangements, the barrier 70 may be laminated to the protective layer 81.

Referring to FIG. 7J, portions of the protective layers 80A exposed to the cavities C1 and C2 may be removed to form a protective layer 80. In some arrangements, the conductive layer 110 is exposed by the protective layer 80 and exposed to the cavity C1. In some arrangements, the conductive layer 101 is exposed by the protective layer 80 and exposed to the cavity C2.

Referring to FIG. 7K, an optical emitter 30 may be disposed in the cavity C1, and an optical receiver 40 may be disposed in the cavity C2. As such, the optical package structure 4A is formed.

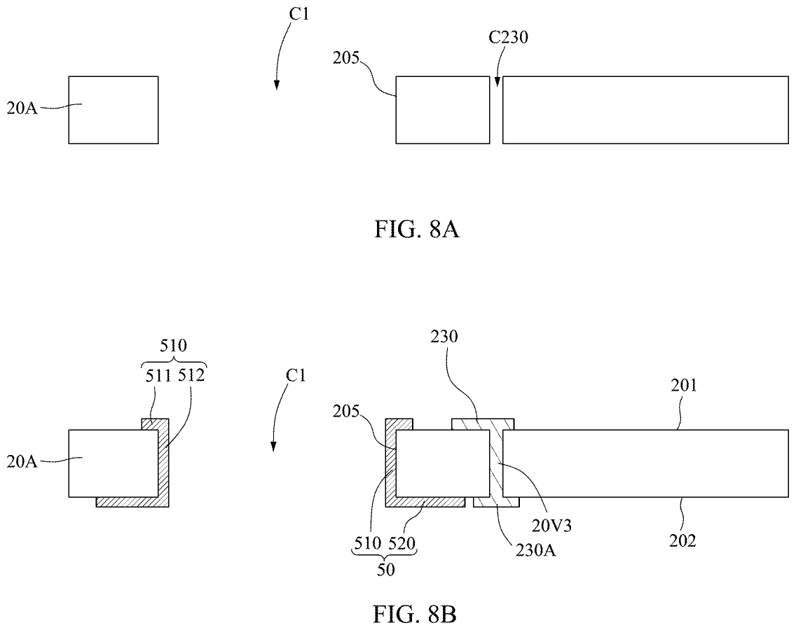

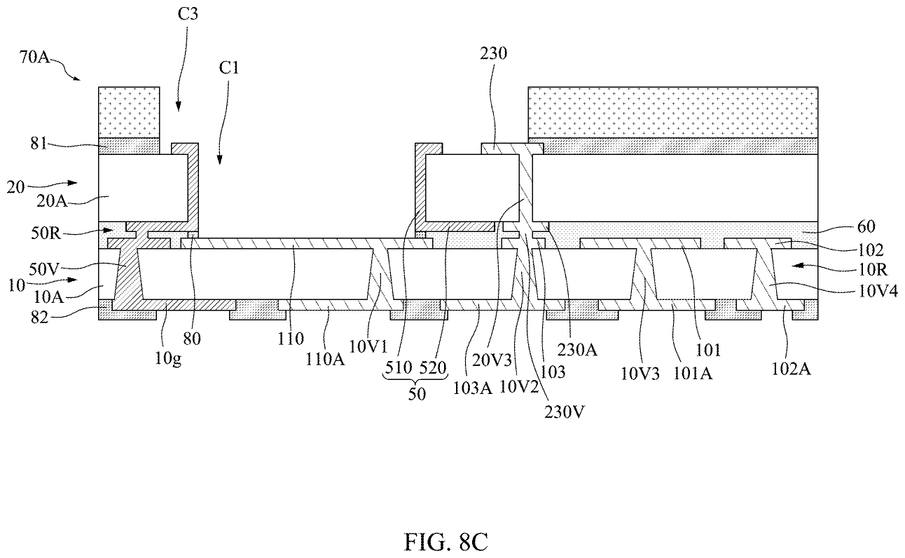

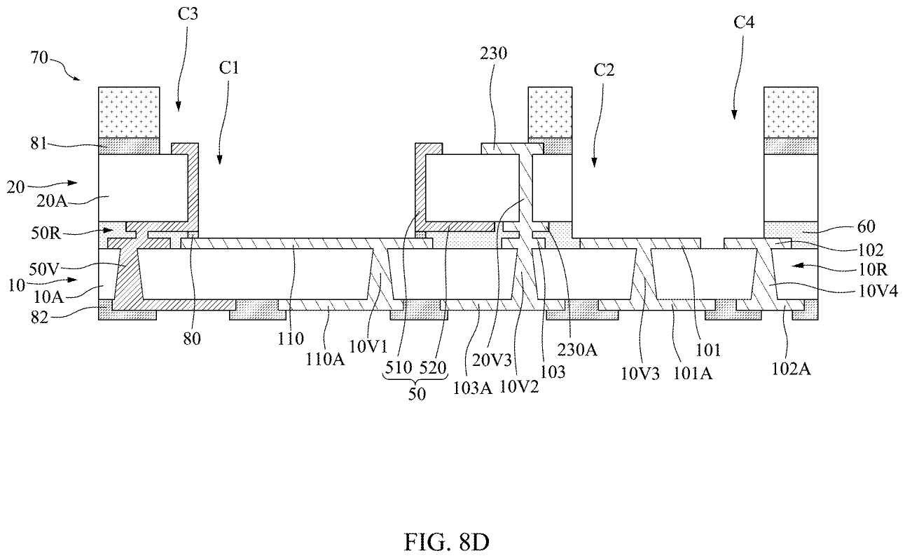

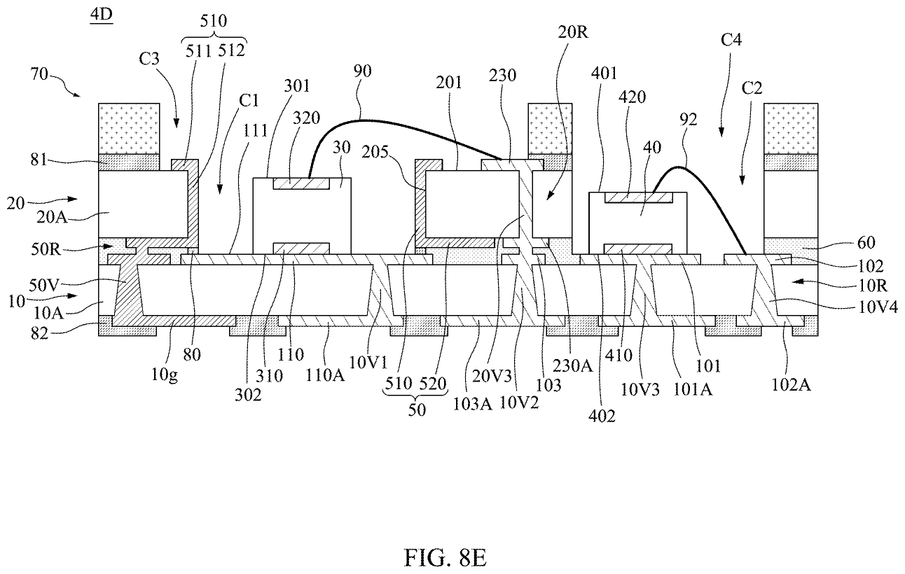

FIG. 8A, FIG. 8B, FIG. 8C, FIG. 8D, and FIG. 8E illustrate various stages of an exemplary method for manufacturing an optical package structure 4D in accordance with some arrangements of the present disclosure.

Referring to FIG. 8A, a base layer 20A may be provided, and a cavity C1 and a through hole C230 may be formed in the base layer 20A. In some arrangements, the base layer 20A may be or include an insulating material or a dielectric material.

Referring to FIG. 8B, a circuit structure 20R and an electrical shielding element 50 may be formed. In some arrangements, the circuit structure 20R includes conductive layers 230 and 230A and a conductive via 20V3. In some arrangements, the electrical shielding element 50 includes a portion 510 including a vertical part 512 on a sidewall of the cavity C1 and an extension 511 partially covering a surface 201 (or the top surface) of the base layer 20A. In some arrangements, the electrical shielding element 50 further includes a portion 520 partially covering a surface 202 (or the bottom surface) of the base layer 20A. The conductive layers 230 and 230A, the conductive via 20V3, and the electrical shielding element 50 may be formed by plating.

Referring to FIG. 8C, operations similar to those illustrated in FIGS. 6C-6G may be performed to provide a base layer 10A and form the circuit structure 10R, the electrical shielding element 50, adhere the base layer 20A to the base layer 10A, and form the protective layers 80, 81, and 82. Next, a barrier layer 70A including a through hole C3 may be formed over the substrate 20. In some arrangements, the barrier layer 70A may be laminated to the protective layer 81.

Referring to FIG. 8D, a cavity C2 may be formed in the base layer 20A, and a through hole C4 may be formed in the barrier layer 70A to form a barrier 70 including the through holes C3 and C4. In some arrangements, the cavity C2 and the through hole C4 are formed in one operation, for example, by a single mechanical drilling operation or a single laser drilling operation. In some arrangements, the through hole C4 substantially aligns with the cavity C2.

Referring to FIG. 8E, an optical emitter 30 may be disposed in the cavity C1, and an optical receiver 40 may be disposed in the cavity C2. As such, the optical package structure 4D is formed.

In some cases, the two through holes of the barrier may be designed to be relatively close to each other; that is, the adjacent through holes are designed to be separated from each other by a relatively small distance. As a result, the small distance between the through holes may be too narrow, such that the two through holes cannot be formed within the relatively thin barrier before the barrier is laminated to the substrates. In contrast, according to some arrangements of the present disclosure, the barrier with one through hole C3 is laminated to the substrates, such that the substrates can serve as a support for the relatively thin barrier, and then the second through hole C4 can be formed in the barrier while the barrier together with the substrates have a relatively high structural strength. In addition, the cavity C2 and the through hole C4 can be formed by a single operation, and thus the cavity C2 and the through hole C4 are aligned with each other. Therefore, even with a predetermined distance or width between the through holes C3 and C4 is relatively small, the structure as well as the process for forming the structure can provide a relatively good workability and a relatively satisfactory structural strength. Accordingly, the yield can be improved.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to +10% of that numerical value, such as less than or equal to +5%, less than or equal to +4%, less than or equal to +3%, less than or equal to +2%, less than or equal to +1%, less than or equal to +0.5%, less than or equal to +0.1%, or less than or equal to +0.05%. For example, a first numerical value can be deemed to be “substantially” the same or equal to a second numerical value if the first numerical value is within a range of variation of less than or equal to +10% of the second numerical value, such as less than or equal to +5%, less than or equal to +4%, less than or equal to +3%, less than or equal to +2%, less than or equal to +1%, less than or equal to +0.5%, less than or equal to +0.1%, or less than or equal to +0.05%. For example, “substantially” perpendicular can refer to a range of angular variation relative to 90° that is less than or equal to +10°, such as less than or equal to +5°, less than or equal to +4°, less than or equal to +3°, less than or equal to +2°, less than or equal to +1°, less than or equal to +0.5°, less than or equal to +0.1°, or less than or equal to +0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An optical package structure, comprising:
a first substrate;
a second substrate over the first substrate, wherein the first substrate and the second substrate collectively define a first cavity;
a first optical component disposed in the first cavity;
a second optical component disposed over the first substrate; and
an electrical shielding element disposed adjacent to a sidewall of the first cavity and between the first optical component and the second optical component.

2. The optical package structure as claimed in claim 1, wherein the electrical shielding element covers the sidewall of the first cavity.

3. The optical package structure as claimed in claim 1, wherein the electrical shielding element is embedded in the second substrate and spaced apart from the sidewall of the first cavity by a portion of the second substrate.

4. The optical package structure as claimed in claim 1, further comprising a conductor directly connected to the first optical component and the second substrate.

5. The optical package structure as claimed in claim 4, wherein the second substrate is electrically connected to the first substrate and the first optical component.

6. The optical package structure as claimed in claim 1, wherein the electrical shielding element extends along the sidewall to a surface of the second substrate facing the first substrate.

7. The optical package structure as claimed in claim 6, further comprising a connection element electrically connecting the electrical shielding element to a ground element of the first substrate.

8. The optical package structure as claimed in claim 7, further comprising an adhesive layer between the first substrate and the second substrate and encapsulating the connection element.

9. The optical package structure as claimed in claim 1, wherein the second substrate defines a second cavity for accommodating the second optical component.

10. The optical package structure as claimed in claim 9, wherein an elevation of a top surface of the second optical component is higher than an elevation of a top portion of the first cavity with respect to the first substrate.

11. The optical package structure as claimed in claim 10, further comprising a light block structure disposed over the second substrate and between the first optical component and the second optical component.

12. The optical package structure as claimed in claim 1, wherein the first substrate comprises a conductive layer exposed to the first cavity and spaced apart from the electrical shielding element by a protective layer.

13. The optical package structure as claimed in claim 12, further comprising an adhesive layer configured to adhere the first substrate and the second substrate and directly contacting the protective layer, the electrical shielding element, and the conductive layer.

14. The optical package structure as claimed in claim 1, wherein the first substrate comprises a first circuit structure electrically connected to the first optical component and a second circuit structure electrically connected to the second optical component, and the electrical shielding element further comprises a portion between the first circuit structure and the second circuit structure.

15. An optical package structure, comprising:
a first substrate comprising a first circuit structure;
a second substrate comprising a second circuit structure;
an adhesive layer between the first substrate and the second substrate; and
a shielding structure at least partially encapsulated by the adhesive layer and configured to reduce an electromagnetic interference between the first circuit structure and the second circuit structure.

16. The optical package structure as claimed in claim 15, further comprising:
an optical emitter disposed on the first circuit structure; and
an optical receiver disposed on the second circuit structure,
wherein the shieling structure comprises a portion between the optical emitter and the optical receiver and configured to reduce a light interference therebetween.

17. The optical package structure as claimed in claim 16, wherein the shieling structure further comprises a connection portion extending into the first substrate and electrically connected to a ground element of the first substrate.

18. An optical package structure, comprising:
a substrate structure;
an optical receiver over the substrate structure; and
a limitation structure over the substrate structure and configured to reduce a first light reflected from the limitation structure to the optical receiver.

19. The optical package structure as claimed in claim 18, wherein the substrate structure and the limitation structure collectively define a cavity for accommodating an optical emitter, and the optical package structure further comprises a block structure disposed adjacent to the cavity and configured to reflect a second light from the optical emitter.

20. The optical package structure as claimed in claim 19, wherein the block structure and the limitation structure are disposed between the optical emitter and the optical receiver.
